(19) United States
(12) Patent Application Publication
(10) Pub. No.: US 2025/0239578 A1
(43) Pub. Date: Jul. 24, 2025

(54) OPTICAL CONNECTOR UNIT FOR A PHOTONIC ASSEMBLY AND METHODS FOR FORMING THE SAME

(71) Applicant: Taiwan Semiconductor Manufacturing Company Limited, Hsinchu (TW)

(72) Inventors: Tso-Jung Chang, Taoyuan City (TW); Chih-Peng Lin, Hsinchu (TW); Jeng-Shien Hsieh, Kaohsiung (TW); Chieh-Yen Chen, Taipei City (TW)

(21) Appl. No.: 18/631,092

(22) Filed: Apr. 10, 2024

Related U.S. Application Data
(60) Provisional application No. 63/623,491, filed on Jan. 22, 2024.

(51) Int. Cl. H01L 25/18; G02B 6/12; H01L 23/00; H01L 23/538; H01L 25/00; H01L 25/16

(52) U.S. Cl. CPC H01L 25/18; H01L 23/5386; H01L 24/06; H01L 24/08; H01L 24/80; H01L 25/167; H01L 25/50; G02B 6/12; H01L 2224/06102; H01L 2224/06181; H01L 2224/08145; H01L 2224/08225; H01L 2224/80357; H01L 2224/80379; H01L 2224/80896; H01L 2924/0544

(57) ABSTRACT

A passive optical interposer is provided, which includes interposer dielectric material layers having formed therein interposer waveguides and interposer bonding pads is provided. A first assembly is provided, which includes a first semiconductor die and at least one first photonic die including first photonic devices and first waveguides. A second assembly is provided, which includes a second semiconductor die and at least one second photonic die including second photonic devices and second waveguides. The first assembly is attached to the passive optical interposer. A subset of the first waveguides are optically coupled to a first subset of the interposer waveguides through evanescent coupling. The second assembly is attached to the passive optical interposer. A subset of the second waveguides are optically coupled to a second subset of the interposer waveguides through evanescent coupling. The first semiconductor die and the second semiconductor die are coupled through optical signal transmission paths.

### RELATED APPLICATIONS

This application claims priority from U.S. Provisional Application Ser. No. 63/623,491 entitled “New Memory Interface for Near Memory Computing” and filed on Jan. 22, 2024, the entire contents of which are incorporated herein by reference for all purposes.

### BACKGROUND

Various types of processing units are used in modern computing. Central processing units (CPUs) serve as the general-purpose brains of computers, handling a wide array of tasks but with a focus on sequential processing. Graphics processing units (GPUs) are specialized for parallel processing, making them ideal for graphics rendering and computational tasks that may be divided into smaller operations. Tensor processing units (TPUs), developed specifically for neural network machine learning, offer optimized performance for artificial intelligence (AI) applications by accelerating tensor computations. Additionally, field-programmable gate arrays (FPGAs) provide a flexible hardware solution that may be reprogrammed for specific tasks, offering a balance between the specialized processing of GPUs and TPUs and the general applicability of CPUs. This variety of processors under the xPU umbrella provides tailored, high-efficiency solutions for a broad spectrum of computational challenges.

Overall performance of a high-end, high performance computer may be limited by a phenomenon referred to as a “memory wall.” The memory wall refers to the discrepancy between operational speed of a processor unit and memory latency, i.e., a situation in which the processor unit does not process data because the data has not arrived from the memory. While processing units have improved with regard to speed and efficiency due to advancements in semiconductor technology and design methodologies, the memory speed, i.e., the time it takes to access data from the main memory, has not improved at the same pace. As a result, the memory wall represents a bottleneck in the field of high-performance computing (HPC) and artificial intelligence (AI) processing, posing a formidable challenge to the efficiency of processing units (xPUs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a photonic device wafer including an array of photonic dies according to an embodiment of the present disclosure. The inset provides a magnified view of one of the photonic dies.

FIG. 2A is a vertical cross-sectional view of an assembly of a semiconductor wafer including an array of semiconductor dies and photonic dies bonded to the semiconductor dies according to an embodiment of the present disclosure.

FIG. 2B is a vertical cross-sectional view of the assembly after formation of a dielectric matrix layer according to an embodiment of the present disclosure.

FIG. 2C is a vertical cross-sectional view of the assembly after formation of connection via structures through the dielectric matrix layer according to an embodiment of the present disclosure.

FIG. 2D is a vertical cross-sectional view of a composite die including a semiconductor die and at least one photonic die that is obtained by singulation of the assembly illustrated in FIG. 2C.

FIG. 3 is a vertical cross-sectional view of an additional composite die including a semiconductor die and at least one photonic die according to an embodiment of the present disclosure.

FIG. 4A is a vertical cross-sectional view of an in-process passive optical interposer after formation of interposer front bonding pads according to an embodiment of the present disclosure.

FIG. 4B is a vertical cross-sectional view of the in-process passive optical interposer after thinning the semiconductor substrate according to an embodiment of the present disclosure.

FIG. 4C is a vertical cross-sectional view of a passive optical interposer after formation of interposer backside bonding pads according to an embodiment of the present disclosure.

FIG. 4D is a vertical cross-sectional view of a bonded assembly including the passive optical interposer and a plurality of composite dies according to an embodiment of the present disclosure.

FIG. 4E is a vertical cross-sectional of the bonded assembly after formation of a molding compound frame around the composite dies according to an embodiment of the present disclosure.

FIG. 5A is a schematic representation of an exemplary scheme for providing optical links through the passive optical interposer to and from the composite dies within the bonded assembly of FIG. 4E.

FIG. 5B is a schematic representation of an exemplary scheme for providing optical links through the passive optical interposer to and from the composite dies within another exemplary bonded assembly.

FIG. 5C is a schematic representation of an exemplary scheme for providing optical links through the passive optical interposer to and from the composite dies within yet another exemplary bonded assembly.

FIG. 6 is a structure formed by attaching the bonded assembly of FIG. 4E to a packaging substrate according to an embodiment of the present disclosure.

FIG. 7A is a vertical cross-sectional view of a bonded assembly including an array of photonic-electronic die assemblies according to an embodiment of the present disclosure. The inset provides a magnified view of a photonic-electronic die assembly.

FIG. 7B is a vertical cross-sectional view of the bonded assembly of FIG. 7A after formation of electronic-die molding compound frames according to an embodiment of the present disclosure. The inset provides a magnified view of a photonic-electronic die assembly.

FIG. 7C is a vertical cross-sectional view of a photonic-electronic die assembly after singulation of the wafer illustrated in FIG. 7B.

FIG. 8A is a vertical cross-sectional view of an assembly of a semiconductor wafer including an array of semiconductor dies and photonic-electronic die assemblies bonded to the semiconductor dies according to an embodiment of the present disclosure.

FIG. 8B is a vertical cross-sectional view of the assembly after formation of a dielectric matrix layer according to an embodiment of the present disclosure.

FIG. 8C is a vertical cross-sectional view of the assembly after formation of connection via structures through the dielectric matrix layer according to an embodiment of the present disclosure.

FIG. 8D is a vertical cross-sectional view of a composite die including a semiconductor die and at least one photonic die that is obtained by singulation of the assembly illustrated in FIG. 8C.

FIG. 9 is a vertical cross-sectional view of an additional composite die including a semiconductor die and at least one photonic die according to an embodiment of the present disclosure.

FIG. 10A is a vertical cross-sectional view of a bonded assembly including a passive optical interposer and a plurality of composite dies according to an embodiment of the present disclosure.

FIG. 10B is a vertical cross-sectional of the bonded assembly after formation of a molding compound frame around the composite dies according to an embodiment of the present disclosure.

FIG. 11 is a structure formed by attaching the bonded assembly of FIG. 10B to a packaging substrate according to an embodiment of the present disclosure.

FIG. 12 is a structure formed by attaching an alternative configuration of the bonded assembly of FIG. 10B to a packaging substrate according to an embodiment of the present disclosure.

FIG. 13 is a schematic for optical transmission of data between a pair of processing units located in different processor dies according to an embodiment of the present disclosure.

FIG. 14 is a flowchart illustrating general processing steps for forming a photonic semiconductor package of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Elements with the same reference numerals are presumed to be the same element or similar elements, and are presumed to have the same material composition and provide the same function, unless expressly described otherwise.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise. As used herein, an element or a system “configured for” a function or an operation or “configured to” provide or perform a function or an operation refers to an element or a system that is provided with hardware, and with software as applicable, to provide such a function or such an operation as described in the present disclosure, and as known in the art in the event any details of such hardware or such software are not expressly described herein.

A memory wall refers to a bottleneck in data transfer between the processing unit and memory, hampering overall system performance and efficiency. Various embodiments of the present disclosure address severe challenges in the realm of high-performance computing (HPC) and artificial intelligence (AI) processing, specifically targeting the memory wall problem faced by high-end high-performance processing units (xPUs). According to an aspect of the present disclosure, processing units and memories may be optically linked by waveguides formed within a passive optical interposer. The optical links provide faster and more efficient data exchange between a memory and a processing unit, and between processing units. Semiconductor dies may be bonded to the passive optical interposer through hybrid bonding (which uses a combination of metal-to-metal bonding with bonding pads and dielectric-to-dielectric bonding between dielectric layers). The semiconductor dies may be laterally spaced apart from one another by sufficient lateral spacing to avoid excessively high local heat generation. Thus, a sustainable path for high-performance computing systems is provided.

The optical links provide integration of external memories into the cache system of processing units. The optical connections provide high-bandwidth data transmission paths across multiple semiconductor dies, enabling the processing units to receive data from memory dies more effectively and to handle intensive computational tasks more efficiently. Optical interconnection to and from semiconductor dies through waveguides formed within a passive optical interposer avoids, or alleviates, the adverse thermal effects of an overheating die on an adjacent die, which may occur around a power-intensive semiconductor die such as a vertical stack of dynamic random access memories (DRAMs). The memory wall caused by data latency may be reduced through the integration of a memory in an external memory die into a processing unit's cache system through optical links. Since the optical links provide efficient long-distance signal transmission paths with minimal signal loss, the size of the passive optical interposer is limited only by manufacturing considerations. A large passive optical interposer having a maximum lateral dimension up to 450 mm or more may be used to provide interconnections to and from a massive array of processing units and memory dies. Embodiments of the present disclosure provide an advanced memory interface tailored for near-memory computing, such as a memory interface for processing units used for high-performance computing (HPC) and artificial intelligence (AI) applications. Thus, embodiments of the present disclosure not only address the inherent latency in a computing system including interconnected processing units and memory dies, but also introduces a method to scale performance without the proportional increase in power consumption or heat generation.

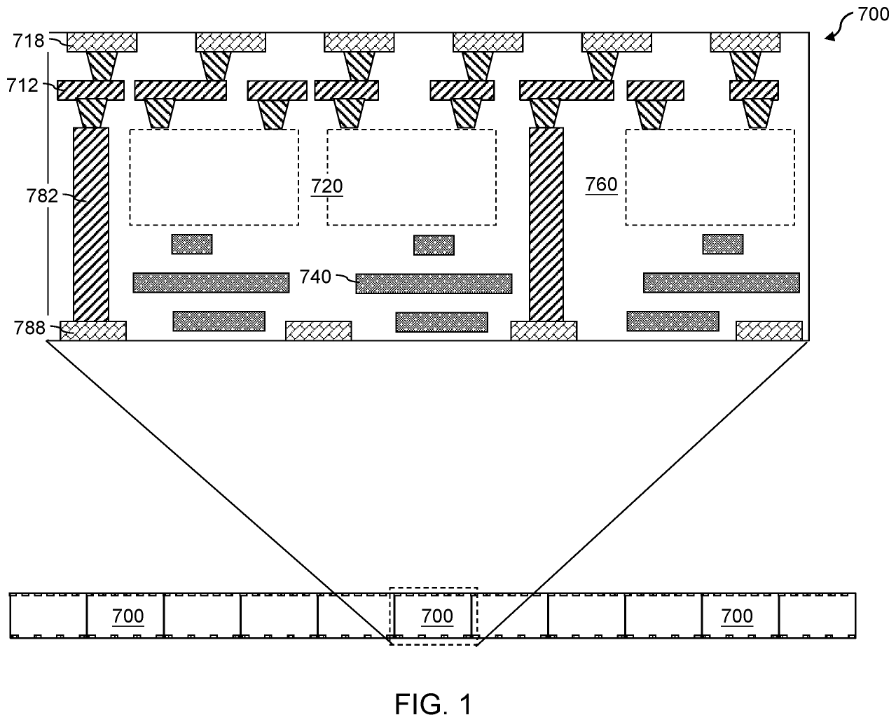

Referring to FIG. 1, a photonic device wafer including an array of photonic dies 700 is illustrated. The array of photonic dies 700 may be formed as a two-dimensional array of photonic dies 700 on a carrier wafer (not illustrated), and the carrier wafer may be subsequently detached from the two-dimensional array of photonic dies 700. Each photonic die 700 may comprise distal photonic-die bonding pads 788, photonic-die dielectric material layers 760, waveguides 740, photonic devices 720 comprising photonic transducers, photonic-die through-dielectric via structures 782 electro-optically connected to a subset of the distal photonic-die bonding pads 788, photonic-die metal interconnect structures 712, and proximal photonic-die bonding pads 718.

The distal photonic-die bonding pads 788 may comprise metal-to-metal bonding pads configured for metal-to-metal bonding. As used herein, a “metal-to-metal” bonding refers to a bonding in which to metal surfaces are directly bonded to each other without any intervening material portion such as a solder material portion. Thus, atomic interdiffusion of metal atoms may occur across a bonding interface, and grain growth and recrystallization of metallic materials may occur during a metal-to-metal bonding. In one embodiment, the distal photonic-die bonding pads 788 may comprise copper bonding pads having copper surfaces as bonding surfaces. In one embodiment, a first subset of the distal photonic-die bonding pads 788 may be electrically connected to a respective one of the proximal photonic-die bonding pads 718, and a second subset of the distal photonic-die bonding pads 788 may be electrically isolated, i.e., not connected to any active electrical node. In this embodiment, the second subset of the distal photonic-die bonding pads 788 may be dummy bonding pads, i.e., electrically inactive bonding pads. The maximum lateral dimension of each distal photonic-die bonding pad 788 may be in a range from 1 nm to 100 nm, such as from 3 nm to 30 nm, although lesser and greater maximum lateral dimensions may also be used.

The photonic-die dielectric material layers 760 may comprise interlayer dielectric (ILD) materials known in the art, which include silicon oxide, silicon nitride, silicon oxynitride, silicon carbide nitride, etc. In one embodiment, the interlayer dielectric materials may comprise, and/or may consist of, at least one inorganic dielectric material. The photonic-die dielectric material layers 760 may be deposited layer by layer. Deposition processes for depositing the photonic-die dielectric material layers 760 may be temporally interlaced with processing steps for forming the waveguides 740 and the photonic devices 720.

The waveguides 740 may be formed over multiple levels by depositing and patterning a waveguide material. For example, the waveguide material may comprise silicon or silicon nitride. The widths and the thicknesses of the waveguides 740 may be selected based on the wavelengths of the optical signals to be used for optical communication. For a wavelength range from 700 nm to 1,600 nm to be used for optical communication, the widths and thicknesses of the waveguides 740 may be in a range from 200 nm to 1,000 nm, although lesser and greater widths and/or thicknesses may also be used. According to an aspect of the present disclosure, a subset of the waveguides 740 may be located in proximity to a horizontal plane including physically exposed surfaces of the distal photonic-die bonding pads 788, and may be optically coupled to the photonic devices 720 through a respective subset of the waveguides 740. Evanescent coupling between neighboring pairs of waveguides 740 may provide optical connection between the subset of the waveguides 740 that are proximal to the horizontal plane including physically exposed surfaces of the distal photonic-die bonding pads 788 and a respective one of the photonic devices 720.

The photonic devices 720 may comprise any type of photonic transducers known in the art. Photonic transducers that may be used for the photonic devices include laser diodes (which emit light upon application of an electrical signal), light emitting diodes, photodiodes, photoconductors, photoresistors, phototransistors, charge-coupled devices, avalanche photodiodes, fiber optic sensors, quantum dot sensors, optocouplers, opto-isolators, photovoltaic cells, etc. Generally, the photonic devices 720 may comprise any device that converts an electrical signal to photons, and/or converts photons into an electrical signal. The photonic devices 720 are optically coupled to the subset of the waveguides 740 that are located in proximity to the horizontal plane including physically exposed surfaces of the distal photonic-die bonding pads 788.

The photonic-die through-dielectric via structures 782 may comprise vertically-extending conductive via structures that vertically extend through a subset of the photonic-die dielectric material layers 760 located at levels of the waveguides 740 and the photonic devices 720. The photonic die through-dielectric via structures 782 may be formed on a respective one of the distal photonic-die bonding pads 788.

The photonic-die metal interconnect structures 712 may be formed within a subset of the photonic-die dielectric material layers 760 that overlie the photonic devices 720. The photonic-die metal interconnect structures 712 may be connected to, and may overlie, the photonic devices 720 and the photonic-die through-dielectric via structures 782.

The proximal photonic-die bonding pads 718 may comprise metal-to-metal bonding pads configured for metal-to-metal bonding. In one embodiment, the proximal photonic-die bonding pads 718 may comprise copper bonding pads having copper surfaces as bonding surfaces. The proximal photonic-die bonding pads 718 may be electrically connected to the photonic-die metal interconnect structures 712, and may be formed within the topmost dielectric material layer selected from the photonic-die dielectric material layers 760. The top surfaces of the photonic-die metal interconnect structures 712 may be coplanar with the top surface of the topmost dielectric material layer selected from the photonic-die dielectric material layers 760. The maximum lateral dimension of each proximal photonic-die bonding pad 718 may be in a range from 1 nm to 100 nm, such as from 3 nm to 30 nm, although lesser and greater maximum lateral dimensions may also be used.

In one embodiment, the bottommost dielectric layer selected from the photonic-die dielectric material layers 760 may comprise a dielectric material that may be used for dielectric-to-dielectric bonding. In one embodiment, the bottommost dielectric layer selected from the photonic-die dielectric material layers 760 may comprise, and/or may consist of, a silicon oxide material such as undoped silicate glass or a doped silicate glass. In one embodiment, the topmost dielectric layer selected from the photonic-die dielectric material layers 760 may comprise a dielectric material that may be used for dielectric-to-dielectric bonding. In one embodiment, the topmost dielectric layer selected from the photonic-die dielectric material layers 760 may comprise, and/or may consist of, a silicon oxide material such as undoped silicate glass or a doped silicate glass.

The wafer including the two-dimensional array of photonic dies 700 may be diced to singulate the photonic dies 700. A plurality of photonic dies 700 may be provided.

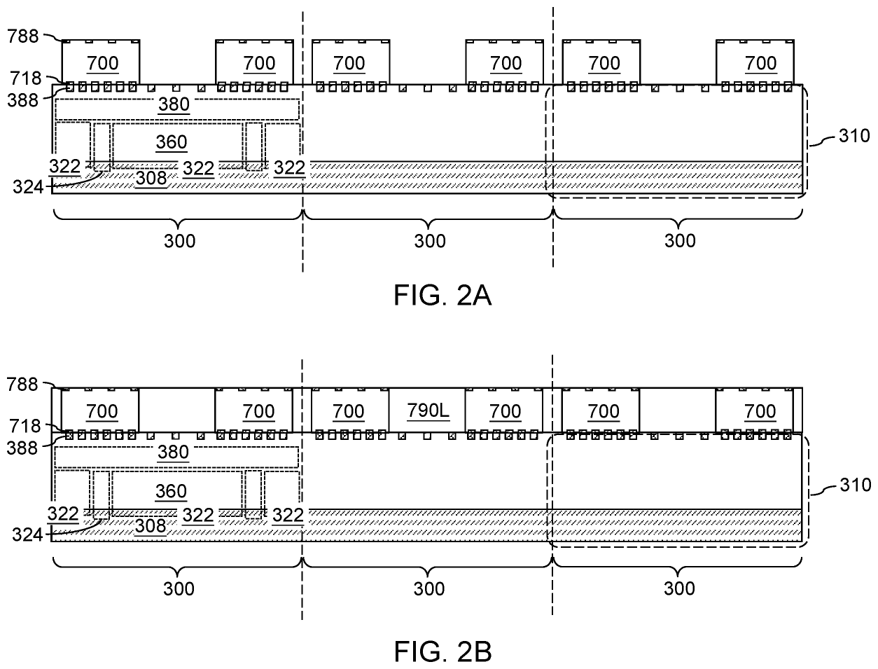

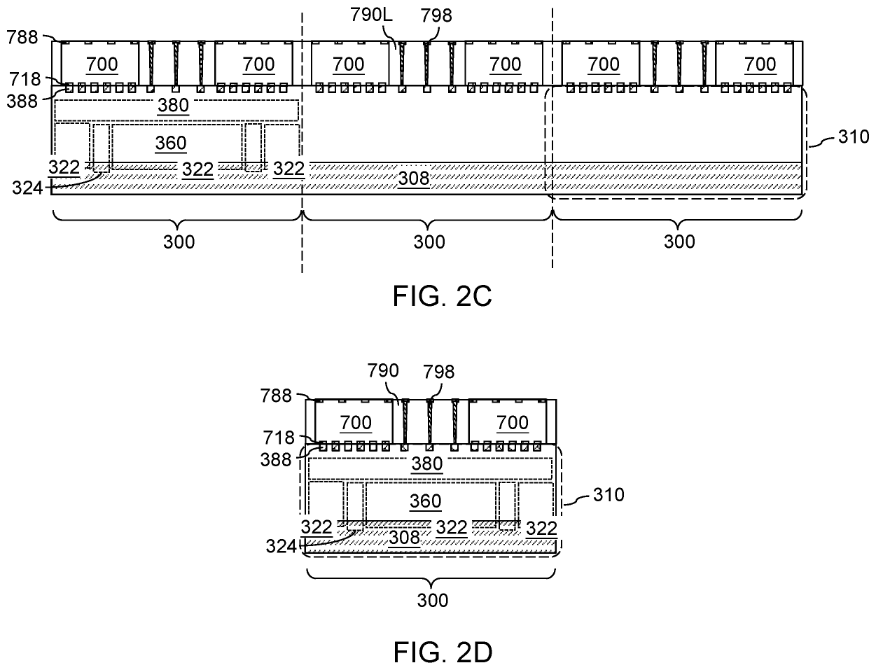

Referring to FIG. 2A, a semiconductor wafer including an array of semiconductor dies may be provided. The array of semiconductor dies may comprise a two-dimensional array of processor dies. The semiconductor wafer may comprise a semiconductor substrate 308, which may be a single crystalline silicon substrate. Each processor die 310 includes at least one processing unit 322. A processing unit may be any of a central processing unit (CPU), a graphics processing unit (GPU), digital signal processor (DSP), a neural processing unit (NPU), an artificial intelligence (AI) accelerator, etc. Further, a processor die may include multiple processing units as in the embodiment of a system-on-integrated-chip (SoIC) die. For example, an SoIC die may comprise a CPU, a GPU, a DSP, and/or an NPU. In addition, a processor die may optionally include a cache memory, which is referred to as an L1 cache memory (i.e., a first-level cache memory) that may comprise a static random access memory (SRAM). Such a cache memory that is present within a processor die is generally referred to as an embedded cache memory.

According to an aspect of the present disclosure, each processor die 310 embeds at least one electronic integrated circuit 324 that is configured to drive a photonic die 700. In this embodiment, each electronic integrated circuit 324 may comprise a CMOS circuit for controlling operation of a photonic die 700. Metal interconnect structures, which are herein referred to as processor-die metal interconnect structures 380, may be provided within each processor die 310. The processor-die metal interconnect structures 380 may be formed within dielectric material layers, which are herein referred to as processor-die dielectric material layers 360.

Bonding pads 388 may be provided within the topmost dielectric material layer selected from the processor-die dielectric material layers 360. The bonding pads 388 within the processor dies 310 are herein referred to as processor-die bonding pads or semiconductor-die bonding pads. The bonding pads 388 within each processor die 310 may comprise at least one set of first bonding pads 388 that are arranged in a mirror image pattern of the pattern of the proximal photonic-die bonding pads 718 of a photonic die 700. In one embodiment, bonding pads 388 within a processor die 310 may comprise multiple sets of first bonding pads 388 that are arranged in mirror image patterns of the pattern of the proximal photonic-die bonding pads 718 of a photonic die 700. The bonding pads 388 within each processor die 310 may comprise a set of second bonding pads 388 which does not belong to any set of first bonding pads 388. In embodiments in which multiple sets of first bonding pads 388 are provided within a processor die 310, a set of second bonding pads 388 may be provided between areas of sets of first bonding pads 388.

The photonic dies 700 as provided after the processing steps described with reference to FIG. 1 may be bonded to the wafer including an array of semiconductor dies, which may be an array of processor dies 310. In one embodiment, the proximal photonic-die bonding pads 718 of each photonic die 700 may be bonded to a respective first subset of bonding pads 388 within the array of semiconductor dies (which may be an array of processor dies 310) by metal-to-metal bonding, such as copper-to-copper bonding. Each bonded assembly of a semiconductor die (such as a processor die 310) and at least one photonic die 700 that is bonded to the semiconductor die constitutes a first assembly 300. A wafer including a two-dimensional array of first assemblies 300 may be provided. Each photonic die 700 may comprise proximal photonic-die bonding pads 718 that are bonded to a respective subset of the bonding pads 388 in a respective underlying semiconductor die (such as a processor die 310), and distal photonic-die bonding pads 788 that are located at an opposite side of the proximal photonic-die bonding pads 718.

Referring to FIG. 2B, a planarizable dielectric material such as undoped silicate glass or a doped silicate glass may be deposited in the gaps between neighboring pairs of photonic dies 700. The planarizable dielectric material may be deposited using a chemical vapor deposition process (such as a plasma-enhanced chemical vapor deposition process), or may be deposited by a spin-coating process. Excess portion s of the planarizable dielectric material may be removed from above the horizontal plane including the top surfaces of the photonic dies 700 by performing a planarization process such as a chemical mechanical polishing (CMP) process. Remaining portions of the planarizable dielectric material constitutes a dielectric matrix layer 790L. The array of photonic dies 700 may be laterally surrounded by the dielectric matrix layer 790L. In one embodiment, the dielectric matrix layer 790L may consist essentially of an inorganic dielectric material such as undoped silicate glass or a doped silicate glass.

Referring to FIG. 2C, a photoresist layer (not shown) may be applied over the top surfaces of the photonic dies 700 and over the top surface of the dielectric matrix layer 790L, and may be lithographically patterned to form discrete openings over the areas of the second subset of the bonding pads 388 of the semiconductor dies (such as the processor dies 310) which are not bonded to the proximal photonic-die bonding pads 718. Discrete cylindrical openings may be formed in the photoresist layer.

A wet etch process may be optionally performed to isotropically etch portions of the dielectric matrix layer 790L that are proximal to bottom portions of the discrete cylindrical openings. An anisotropic etch process may be subsequently performed to transfer the pattern of the discrete cylindrical openings through the dielectric matrix layer 790L. Via cavities vertically extending through the dielectric matrix layer 790L to top surfaces of the second subset of the bonding pads 388 of the semiconductor dies (such as the processor dies 310) which are not bonded to the proximal photonic-die bonding pads 718. In one embodiment, the via cavities may have tapered sidewalls such that the lateral dimension of each via cavity decreases with a vertical distance downward from the photoresist layer. The photoresist layer may be subsequently removed, for example, by ashing.

At least one metallic material may be deposited in the via cavities and over the top surface of the dielectric matrix layer 790L. The at least one metallic material may comprise a combination of a metallic barrier liner material (such as TiN, TaN, WN, or MoN) and a metallic fill material comprising, and/or consisting essentially of, copper. The metallic barrier liner material may be deposited, for example, by chemical vapor deposition or physical vapor deposition. The metallic fill material may be deposited, for example, by electroplating. Excess portions of the at least one metallic material may be removed from above the horizontal plane including the top surfaces of the photonic dies 700. Each remaining portion of the at least one metallic material that fill a respective via cavity constitutes a connection via structure 798. An array of connection via structures 798 may be formed through the dielectric matrix layer 790L on a second subset of the bonding pads 388 within each semiconductor dies (such as a processor die 310).

Referring to FIG. 2D, the wafer including the array of semiconductor dies (such as the processor dies 310), the photonic dies 700, and the dielectric matrix layer 790L may be diced along dicing channels. Each diced portion of the wafer comprises a first assembly 300, which is a composite die including at least two dies. Specifically, each first assembly 300 comprises a semiconductor die (such as a processor die 310), at least one photonic die 700, and a dielectric matrix 790 which is a diced portion of the dielectric matrix layer 790L.

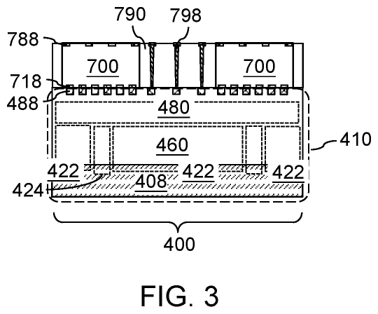

FIG. 3 is a vertical cross-sectional view of an additional composite die including a semiconductor die and at least one photonic die 700 according to an embodiment of the present disclosure. Referring to FIG. 3, a second assembly 400 of a semiconductor die, at least one photonic die 700, and a dielectric matrix 790 is illustrated. The semiconductor die of the second assembly 400 may be a memory die 410, which may comprise a static random access memory (SRAM), a dynamic random access memory (DRAM), a magnetoresistive random access memory (RRAM), a high-bandwidth memory (HBM), or any other type of memory known in the art.

The memory die 410 may comprise a semiconductor substrate 408, and memory devices 422 formed in, on, or over, the semiconductor substrate 408. The memory devices 422 may comprise an SRAM, a DRAM, an RRAM, a HBM, or a combination thereof. According to an aspect of the present disclosure, each memory die 410 embeds at least one electronic integrated circuit 424 that is configured to drive a photonic die 700. In this embodiment, each electronic integrated circuit 324 may comprise a CMOS circuit for controlling operation of a photonic die 700. Metal interconnect structures, which are herein referred to as memory-die metal interconnect structures 480, may be provided within each memory die 410. The memory-die metal interconnect structures 480 may be formed within dielectric material layers, which are herein referred to as memory-die dielectric material layers 460.

Bonding pads 488 may be provided within the topmost dielectric material layer selected from the processor-die dielectric material layers 360. The bonding pads 488 within the memory dies 410 are herein referred to as memory-die bonding pads or semiconductor-die bonding pads. The bonding pads 488 within each memory die 410 may comprise at least one set of first bonding pads 488 that are arranged in a mirror image pattern of the pattern of the proximal photonic-die bonding pads 718 of a photonic die 700. In one embodiment, bonding pads 488 within a memory die 410 may comprise multiple sets of first bonding pads 488 that are arranged in mirror image patterns of the pattern of the proximal photonic-die bonding pads 718 of a photonic die 700. The bonding pads 488 within each memory die 410 may comprise a set of second bonding pads 488 which does not belong to any set of first bonding pads 488. In embodiments in which multiple sets of first bonding pads 488 are provided within a memory die 410, a set of second bonding pads 488 may be provided between areas of sets of first bonding pads 488.

Generally, the processing steps described with reference to FIGS. 2A-2D may be performed with replacement of a wafer including a two-dimensional array of processor dies 310 with a wafer including a two-dimensional array of memory dies 410 to provide multiple instances of the second assembly 400 illustrated in FIG. 3, which is a composite die including a semiconductor die, at least one photonic die 700, and a dielectric matrix 790.

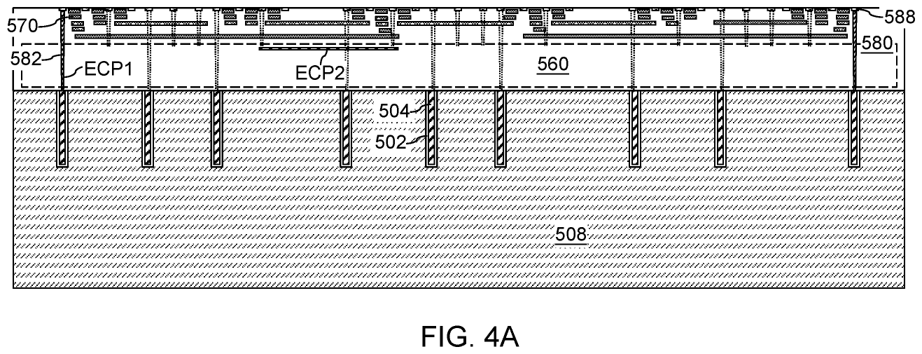

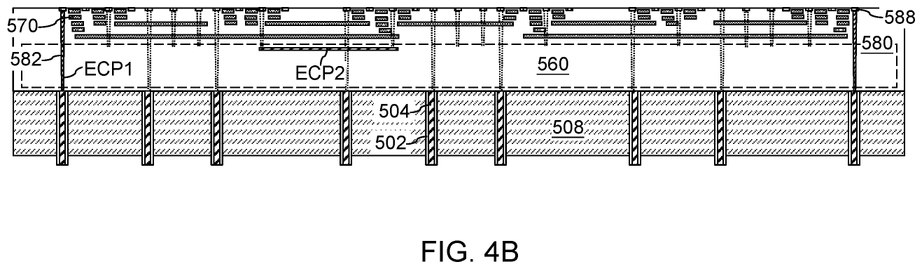

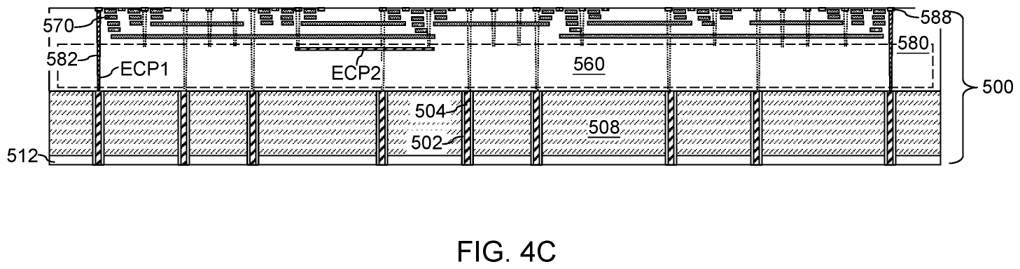

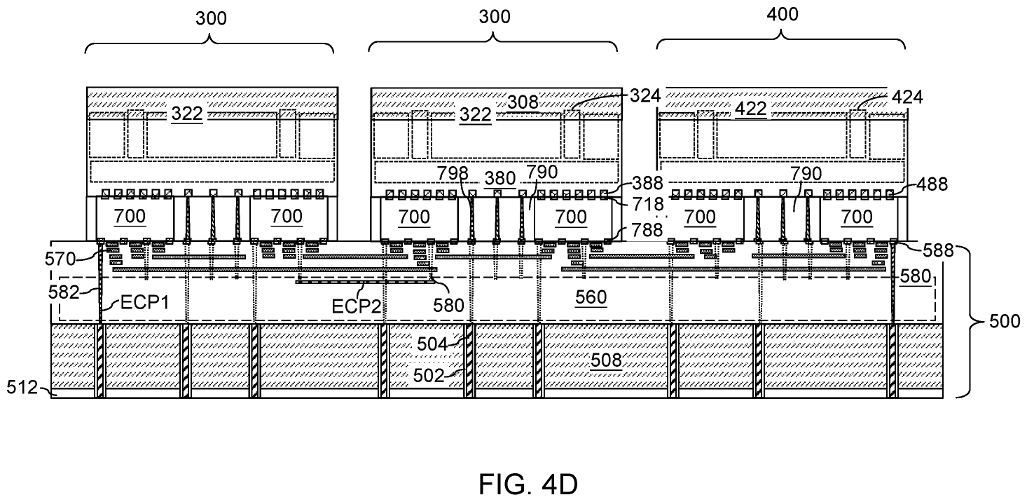

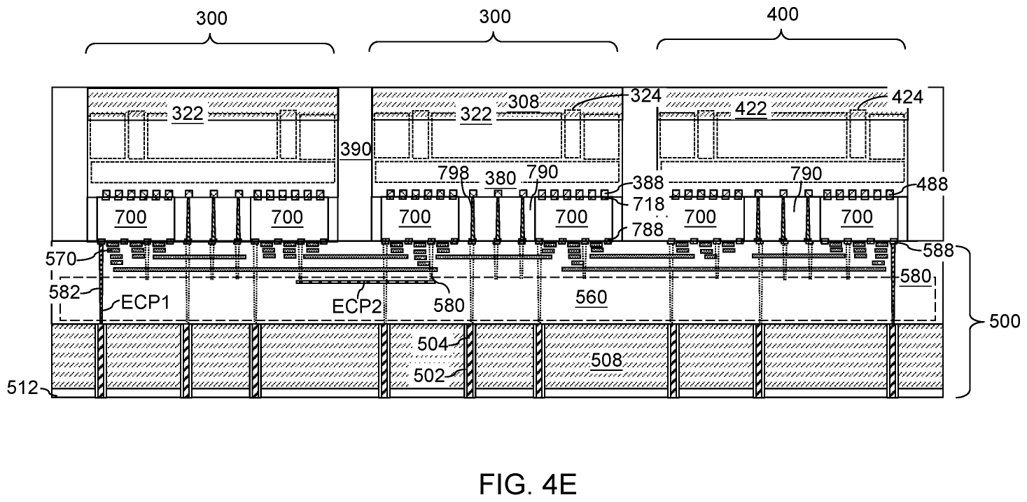

Referring to FIG. 4A, an in-process passive optical interposer according to an embodiment of the present disclosure is illustrated. The in-process passive optical interposer comprises a semiconductor substrate 508 (which may also be referred to as an interposer semiconductor substrate), substrate via cavities vertically extending downward from the top surface of the semiconductor substrate 508 toward the backside surface of the semiconductor substrate 508 and filled with combinations of an insulating spacers 502 and a through-substrate via structure 504, interposer dielectric material layers 560 having formed therein interposer waveguides 570, interposer metal interconnect structures 580, connection via structures 582, and interposer bonding pads 588 (which are also referred to as interposer front bonding pads). A subset of the interposer metal interconnect structures 580 and a subset of the connection via structures 582 are represented by dotted lines to clarify that the interposer metal interconnect structures 580 and a subset of the connection via structures 582 do not generally contact the interposer waveguides 570.

In one embodiment, a wafer including a two-dimensional periodic array of in-process passive optical interposer may be formed. In this embodiment, the illustrated in-process passive optical interposer may be a portion of the wafer, which corresponds to a unit die embedded within the wafer. The semiconductor substrate 508 may be a portion of a commercially available semiconductor wafer such as a single crystalline silicon wafer. The substrate via cavities may be formed by a combination of a lithographic patterning step and an anisotropic etch process. The insulating spacers 502 and the through-substrate via structures 504 may be formed, for example, by sequential deposition of an insulating material layer (such as a silicon oxide layer) and at least one metallic material (which may comprise a combination of a metallic barrier material and a metallic fill material), followed by a planarization process that removes portions of the at least one metallic material and the insulating material layer from above the horizontal plane including the top surface of the semiconductor substrate 508. The illustrated portion of the wafer in FIG. 4A corresponds to a region to be subsequently singulated into a passive optical interposer.

The interposer dielectric material layers 560 may comprise interlayer dielectric (ILD) materials known in the art, which may comprise silicon oxide, silicon nitride, silicon oxynitride, silicon carbide nitride, and/or at least one dielectric metal oxide material (such as aluminum oxide, titanium oxide, etc.). The interposer waveguides 570 may be formed by deposition and patterning of a waveguide material, which may comprise polysilicon, amorphous silicon, or silicon nitride.

The widths and the thicknesses of the interposer waveguides 570 may be selected based on the wavelengths of the optical signals to be used for optical communication. For a wavelength range from 700 nm to 1,600 nm to be used for optical communication, the widths and thicknesses of the interposer waveguides 570 may be in a range from 200 nm to 1,000 nm, although lesser and greater widths and/or thicknesses may also be used. A subset of the interposer waveguides 570 may be located in proximity to a horizontal plane including physically exposed surfaces of the interposer bonding pads 588. According to aspect of the present disclosure, pairs of interposer waveguides 570 that are located in different areas and in proximity to the horizontal plane including physically exposed surfaces of the interposer bonding pads 588 may be optically connected to each other through a respective subset of the interposer waveguides 570 that laterally extends between a respective pair.

Generally, the interposer waveguides 570 that are located in proximity to the horizontal plane including physically exposed surfaces of the interposer bonding pads 588 may be located in areas over which waveguides 740 within photonic dies 700 are to be subsequently positioned to provide optical coupling. Thus, a pair of interposer waveguides 570 located in areas for bonding different photonic dies 700 may be optically coupled to each other through a subset of the interposer waveguides 570.

The connection via structures 582 may vertically extend from a bottom surface of a respective one of the interposer bonding pads 588 to a top surface of a respective one of the through-substrate via structures 504. First electrically conductive paths ECP1 including a contiguous set of an interposer bonding pad 588, a connection via structure 582 and a through-substrate via structure 504 may be formed in the in-process passive optical interposer. Further, second electrically conductive paths ECP2 may be provided between pair of interposer bonding pads 588. Each second electrically conductive path ECP2 may comprise a contiguous combination of two interposer bonding pads 588 and a subset of the interposer metal interconnect structures 580. The subset of the interposer metal interconnect structures 580 may comprise at least two metal via structures and at least one metal line structure.

Referring to FIG. 4B, the backside of the semiconductor substrate 508 may be thinned by grinding, polishing, an isotropic etch process, or an anisotropic etch process. Bottom end surfaces of the insulating spacers 502 may be used as stopper structures during a terminal step of the thinning process, which may comprise a chemical mechanical polishing process or an etch process. Subsequently, the physically exposed backside surface of the semiconductor substrate 508 may be vertically recessed such that the through-substrate via structures 504 protrude outward relative to the physically exposed backside surface of the semiconductor substrate 508.

Referring to FIG. 4C, a backside insulating layer 512 may be deposited on the backside surface of the semiconductor substrate 508. A planarization process may be performed to remove portions of the backside insulating layer 512 that protrudes below the horizontal plane including the backside end surfaces of the through-substrate via structures 504. The wafer may include a two-dimensional array of passive optical interposers 500 after the processing steps of FIG. 4.

Referring to FIG. 4D, a plurality of composite dies (300, 400) may be bonded to the passive optical interposer 500. The plurality of composite dies (300, 400) may comprise at least one first assembly 300 illustrated in FIG. 2D and at least one second assembly illustrated in FIG. 3. Generally, each first assembly 300, i.e., each first composite die, comprises a respective first semiconductor die (such as a processor die 310) and at least one respective first photonic die 700 including first photonic devices 720 and first waveguides 740. Each second assembly 400, i.e., each second composite die, comprises a second semiconductor die (such as a memory die 410) and at least one second photonic die 700 including second photonic devices 720 and second waveguides 740. The first assembly 300 may be attached to the passive optical interposer 500 such that a subset of the first waveguides 740 in each first photonic die 700 are optically coupled to a first subset of the interposer waveguides 570 in the passive optical interposer 500 through evanescent coupling. The second assembly 400 may be attached to the passive optical interposer 500 such that a subset of the second waveguides 740 in each second photonic die 700 are optically coupled to a second subset of the interposer waveguides 570 in the passive optical interposer 500 through evanescent coupling.

Each of the photonic dies 700 comprises proximal photonic-die bonding pads 718 and distal photonic-die bonding pads 788. The distal photonic-die bonding pads 788 are located at an opposite side of the proximal photonic-die bonding pads 718. The distal photonic-die bonding pads 788 and the connection via structures 798 which are located within a first assembly 300 or within a second assembly 400 are bonded to interposer bonding pads 588 within the passive optical interposer 500 by metal-to-metal bonding, such as copper to copper bonding.

A semiconductor package is provided, which includes a passive optical interposer 500 comprising interposer dielectric material layers 560 having formed therein interposer waveguides 570 and interposer bonding pads 588. The semiconductor package includes at least one first composite die (which may be at least one first assembly 300) including a vertical stack of a respective first semiconductor die (such as a processor die 310) and at least one respective first photonic die 700. Each of the at least one first photonic die 700 comprises first photonic devices 720, first waveguides 740, first distal photonic-die bonding pads 788 that are bonded to a first subset of the interposer bonding pads 588, and first proximal photonic-die bonding pads 718 that are bonded to bonding pads 388 of the first semiconductor die (such as a processor die 310). The semiconductor package includes at least one second composite die (which may be at least one second assembly 400) including a vertical stack of a respective second semiconductor die (such as a memory die 410) and at least one respective second photonic die 700. Each of the at least one second photonic die 700 comprises second photonic devices 720, second waveguides 740, second distal photonic-die bonding pads 788 that are bonded to a second subset of the interposer bonding pads 588, and second proximal photonic-die bonding pads 718 that are bonded to bonding pads 488 of the second semiconductor die (such as a memory die 410).

The first distal photonic-die bonding pads 788 of each first photonic die 700 are bonded to the first subset of the interposer bonding pads 588 by metal-to-metal bonding. The second distal photonic-die bonding pads 788 of each second photonic die 700 are bonded to the second subset of the interposer bonding pads 588 by metal-to-metal bonding. First connection via structures 798 within each first assembly 300 may be bonded to a third subset of the interposer bonding pads 588 by metal-to-metal bonding. second connection via structures 798 within each second assembly 400 may be bonded to a fourth subset of the interposer bonding pads 588 by metal-to-metal bonding.

A subset of the interposer waveguides 570 laterally extends from a first region located underneath the at least one first photonic die 700 to a second region located underneath the at least one second photonic die 700. The subset of the interposer waveguides 570 may be optically coupled to waveguides 740 within the at least one first photonic die 700 via evanescent coupling, and may be optically coupled to waveguides 740 within the at least one second photonic die 700 via evanescent coupling.

In one embodiment, dielectric-to-dielectric bonding may be used in addition to metal-to-metal bonding between the passive optical interposer 500 and each of the first assemblies 300 and the second assemblies 400. In one embodiment, each of the at least one first photonic die 700 comprises first photonic-die dielectric material layers 760 having formed therein the first distal photonic-die bonding pads 788 and first waveguides 740, and a surface of the first photonic-die dielectric material layers 760 is bonded to a surface segment of the interposer dielectric material layers 560 by dielectric-to-dielectric bonding (such as silicon oxide-to-silicon oxide bonding). In one embodiment, each of the at least one second photonic die 700 comprises second photonic-die dielectric material layers 760 having formed therein the second distal photonic-die bonding pads 788 and second waveguides 740, and a surface of the second photonic-die dielectric material layers 760 is bonded to a surface segment of the interposer dielectric material layers 560 by dielectric-to-dielectric bonding (such as silicon oxide-to-silicon oxide bonding).

In one embodiment, each first composite die (i.e., each first assembly 300) comprises a first dielectric matrix 790 laterally surrounding the at least one first photonic die 700 and contacting a planar surface of a first semiconductor die (such as a processor die 310), and first connection via structures 798 vertically extending through a first dielectric matrix 790, having first end surfaces that are bonded to a subset of bonding pads 388 within the first semiconductor die, and having second end surfaces that are bonded to a subset of the interposer bonding pads 588. In one embodiment, each second composite die (i.e., each second assembly 400) comprises a second dielectric matrix 790 laterally surrounding the at least one second photonic die 700 and contacting a planar surface of a second semiconductor die (such as a memory die 410), and second connection via structures 798 vertically extending through a second dielectric matrix 790, having second end surfaces that are bonded to a subset of bonding pads 488 within the second semiconductor die, and having second end surfaces that are bonded to a subset of the interposer bonding pads 588.

Referring to FIG. 4E, an encapsulant, such as a molding compound (MC) may be applied into the gaps between neighboring pairs of composite dies (300, 400). The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability. Excess portions of the molding compound may be removed from above the horizontal plane including the top surfaces of the composite dies (300, 400).

The MC may be cured at a curing temperature to form a molding compound matrix layer. The molding compound matrix layer may be a continuous material layer that extends across the entirety of the area of the wafer including the two-dimensional array of passive optical interposers 500 and the composite dies (300, 400) that are bonded to the passive optical interposers 500. A reconstituted wafer is thus formed, which includes the two-dimensional array of passive optical interposers 500, the composite dies (300, 400) thereupon, and the molding compound matrix layer.

The reconstituted wafer may be subsequently diced along dicing channels, which correspond to the boundaries between neighboring pairs of passive optical interposers 500. Each singulated portion of the reconstituted wafer comprises a semiconductor structure including an assembly of a passive optical interposer 500, a plurality of composite dies (300, 400), and a molding compound matrix 390 which is portion of the molding compound matrix layer. Sidewalls of the molding compound matrix 390 may be vertically coincident with sidewalls of the passive optical interposer 500 within each assembly.

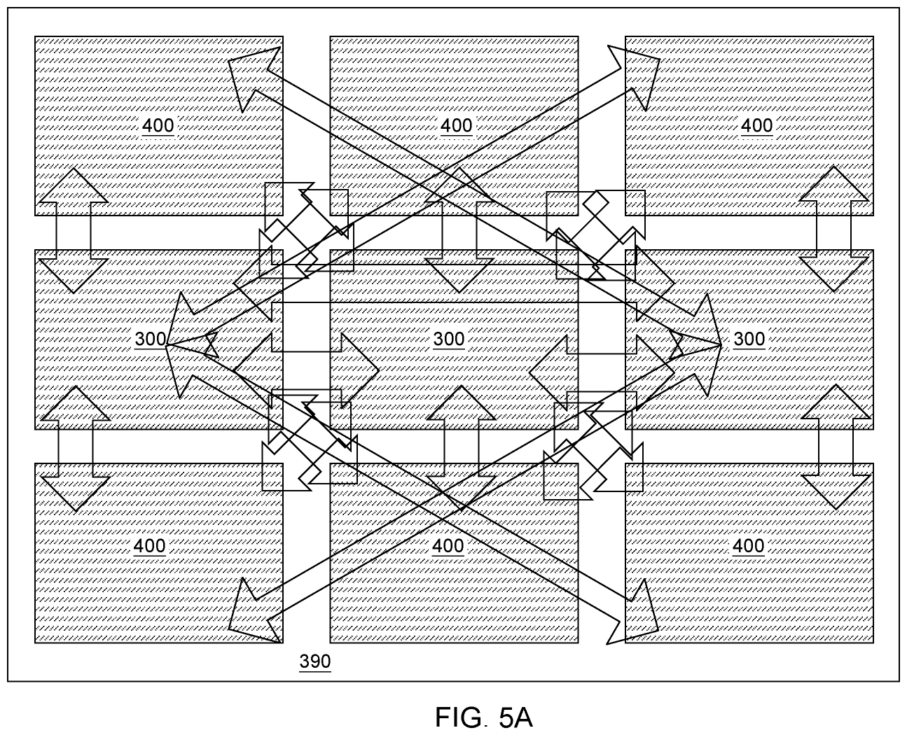

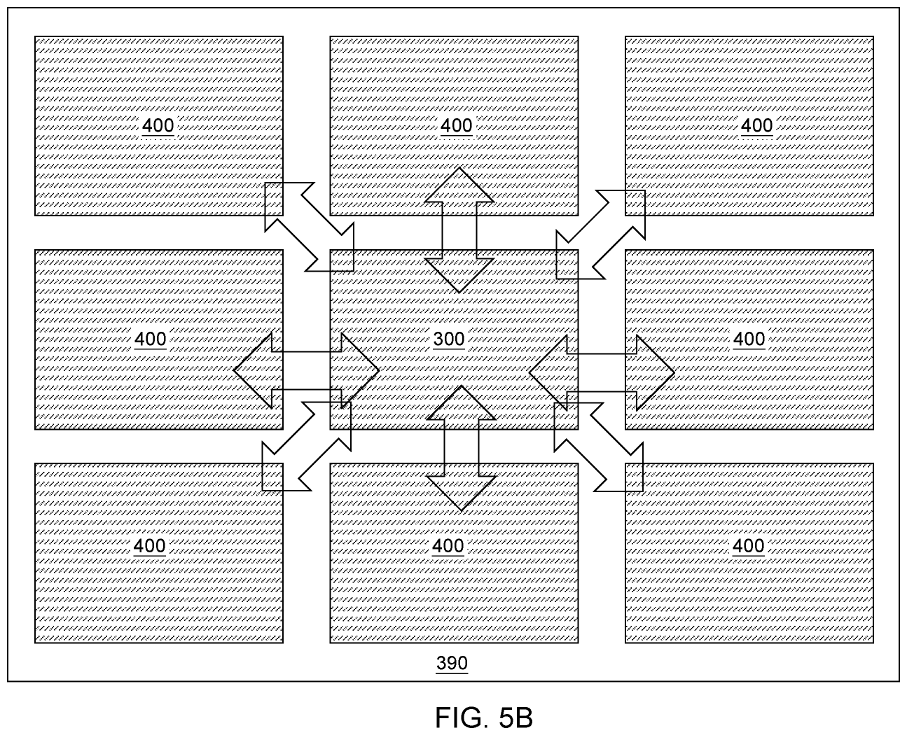

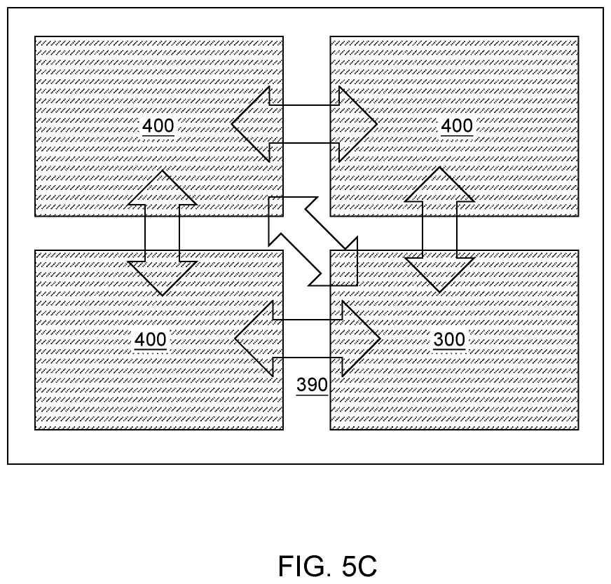

FIG. 5A is a schematic representation of an exemplary scheme for providing optical links through the passive optical interposer 500 to the composite dies within the bonded assembly of FIG. 4E. The bidirectional arrows represent optical connections that are provided to and from the various composite dies (300, 400). In one embodiment, one, a plurality, and/or each, of the processor dies 310 (located within a respective first composite die 300 (i.e., a respective first assembly 300)) may be optically connected to all other processor dies 310 via the interposer waveguides 570. In one embodiment, one, a plurality, and/or each, of the processor dies 310 may be optically connected to all memory dies 410 within the bonded assembly via additional interposer waveguides 570. In one embodiment, one, a plurality, and/or each, of the processor dies 310 may be optically connected to all other processor dies 310 and to all memory dies 410 within the bonded assembly via interposer waveguides 570. In one embodiment, one, a plurality, and/or each of the processor dies 310 may be electrically connected to at least one, and/or each, of the rest of the processor dies 310 via second electrically conductive paths ECP2. In one embodiment, one, a plurality, and/or each of the processor dies 310 may be electrically connected to at least one, and/or each, of the memory dies 410 via second electrically conductive paths ECP2.

While the configuration illustrated in FIG. 5A uses three first assemblies 300 (including three processor dies 310) and six second assemblies 400 (including six memory dies 410), any positive number of first assemblies 300 and any positive number of second assemblies 400 may be optically interconnected to and from one another above a same passive optical interposer 500 through interposer waveguides 570. Electrical connections to and from the assemblies (300, 400) through the second electrically conductive paths ECP2 are optional, and may be omitted in some embodiments.

FIG. 5B is a schematic representation of an exemplary scheme for providing optical links through the passive optical interposer 500 to and from the composite dies within another exemplary bonded assembly. In the configuration illustrated in FIG. 5B, a first assembly 300 and multiple second assemblies 400 are used. In one embodiment, the processor dies 310 within the first assembly 300 may be optically connected to all memory dies 410 within the second assemblies 400 via interposer waveguides 570. In some embodiments, the memory dies 410 may be optically connected to one another through additional interposer waveguides 570.

FIG. 5C is a schematic representation of an exemplary scheme for providing optical links through the passive optical interposer 500 to and from the composite dies within yet another exemplary bonded assembly. In the configuration illustrated in FIG. 5C, a first assembly 300 and multiple second assemblies 400 are used. In one embodiment, the processor dies 310 within the first assembly 300 may be optically connected to all memory dies 410 within the second assemblies 400 via interposer waveguides 570. In some embodiments, the memory dies 410 may be optically connected to one another through additional interposer waveguides 570.

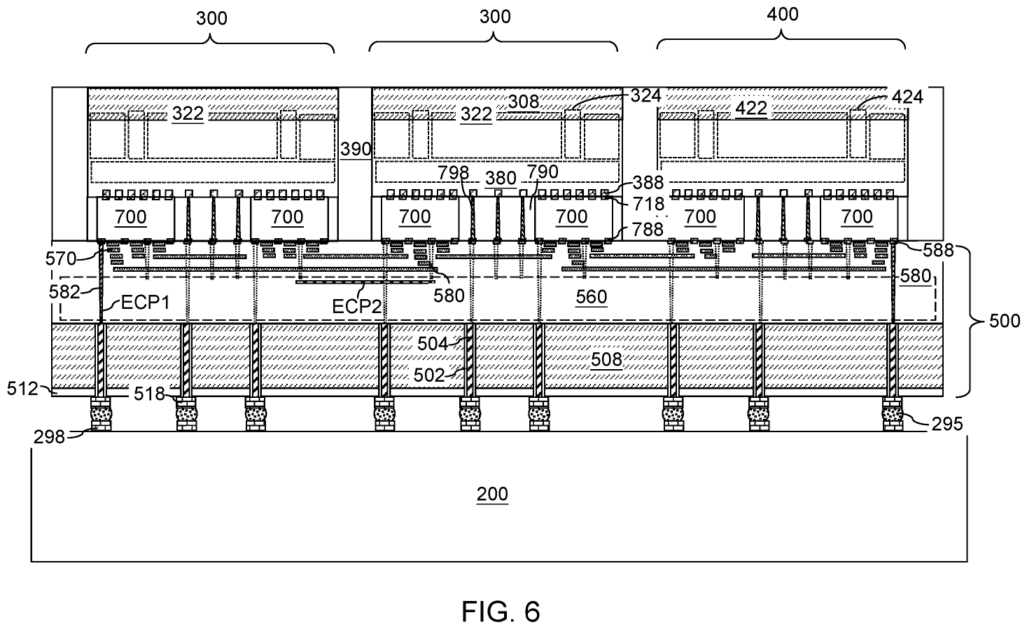

Referring to FIG. 6, backside interposer bonding pads 518 and solder material portions 295 may be formed on the physically exposed backside end surfaces of the through-substrate via structures 504. The backside interposer bonding pads 518 may be configured to solder bonding, such as C4 bonding. For example, each of the backside interposer bonding pads 518 may comprise a layer stack including a metallic barrier liner comprising a conductive metallic nitride material (such as TIN, TaN, WN, or MoN), a copper layer, a metallic diffusion barrier liner comprising a diffusion barrier metallic material such as Ti, TiW, Ta, or TaN, an adhesion layer enhancing the adhesion strength of subsequently deposited layers and comprising a material such as Cr, Ti, or a Cr/Ti alloy, and an under-bump metallization (UBM) layer. The UBM layer may comprise a multi-layer stack such as a layer stack of a copper layer, a nickel layer, and a gold layer. Alternative UBM layer compositions may also be used.

A packaging substrate 200 may be provided. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. The packaging substrate 200 may comprise an array of packaging-substrate bonding pads 298, which may be configured for C4 bonding. The solder material portions 295 may be bonded to the packaging-substrate bonding pads 298 via solder bonding, thereby forming an assembly including a passive optical interposer 500, composite dies (300, 400) bonded to the passive optical interposer 500, a molding compound matrix 390, and a packaging substrate 200.

Referring collectively to FIGS. 1-6, a semiconductor package is provided, which comprises: a passive optical interposer 500 comprising interposer dielectric material layers 560 having formed therein interposer waveguides 570 and interposer bonding pads 588; a first composite die (which may be a composite processor-containing die that may comprise a first assembly 300) including a vertical stack of a first semiconductor die (such as a processor die 310) and at least one first photonic die 700, wherein each of the at least one first photonic die 700 comprises first photonic devices 720, first waveguides 740, first distal photonic-die bonding pads 788 that are bonded to a first subset of the interposer bonding pads 588, and first proximal photonic-die bonding pads 718 that are bonded to bonding pads 388 of the first semiconductor die (such as a processor die 310); and a second composite die (which may be a composite memory-containing die that may comprise a second assembly 400) including a vertical stack of a second semiconductor die (such as a memory die 410) and at least one second photonic die 700, wherein each of the at least one second photonic die 700 comprises second photonic devices 720, second waveguides 740, second distal photonic-die bonding pads 788 that are bonded to a second subset of the interposer bonding pads 588, and second proximal photonic-die bonding pads 718 that are bonded to bonding pads 488 of the second semiconductor die (such as a memory die 410).

In one embodiment, a subset of the interposer waveguides 570 laterally extends from a first region located underneath the at least one first photonic die 700 to a second region located underneath the at least one second photonic die 700. In one embodiment, the first distal photonic-die bonding pads 788 are bonded to the first subset of the interposer bonding pads 588 by metal-to-metal bonding. In one embodiment, each of the at least one first photonic die 700 comprises first photonic-die dielectric material layers 760 having formed therein the first distal photonic-die bonding pads 788 and first waveguides 740; and a surface of the first photonic-die dielectric material layers 760 is bonded to a surface segment of the interposer dielectric material layers 560 by dielectric-to-dielectric bonding.

In one embodiment, the first composite die (which may be a composite processor-containing die that may comprise a first assembly 300) comprises: a first dielectric matrix 790 laterally surrounding the at least one first photonic die 700 and contacting a planar surface of the first semiconductor die (such as a processor die 310); and first connection via structures 798 vertically extending through the first dielectric matrix 790, having first end surfaces that are bonded to a subset of bonding pads within the first semiconductor die (such as a processor die 310), and having second end surfaces that are bonded to a subset of the interposer bonding pads 588.

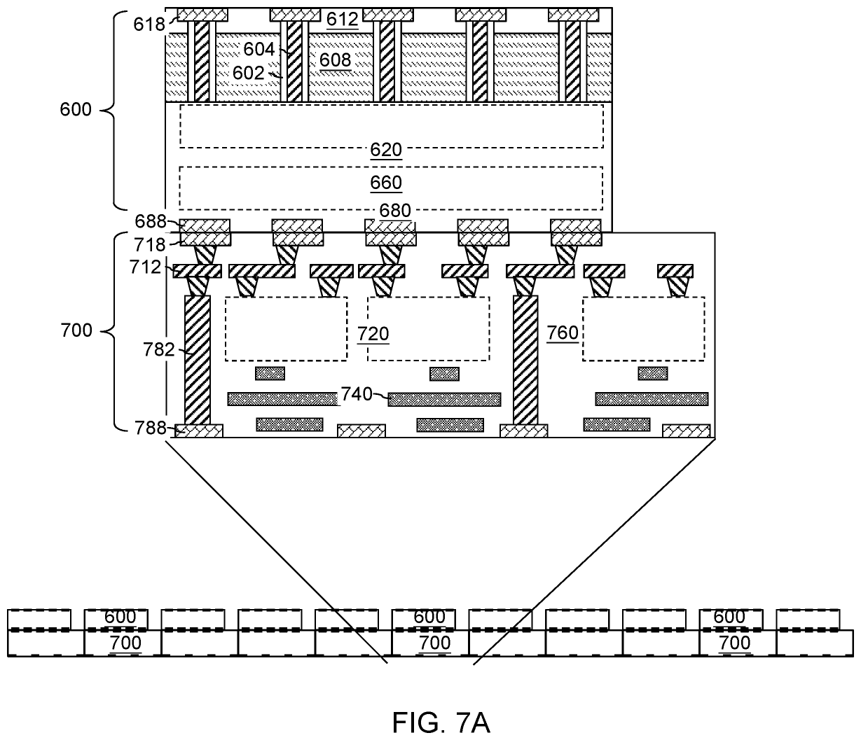

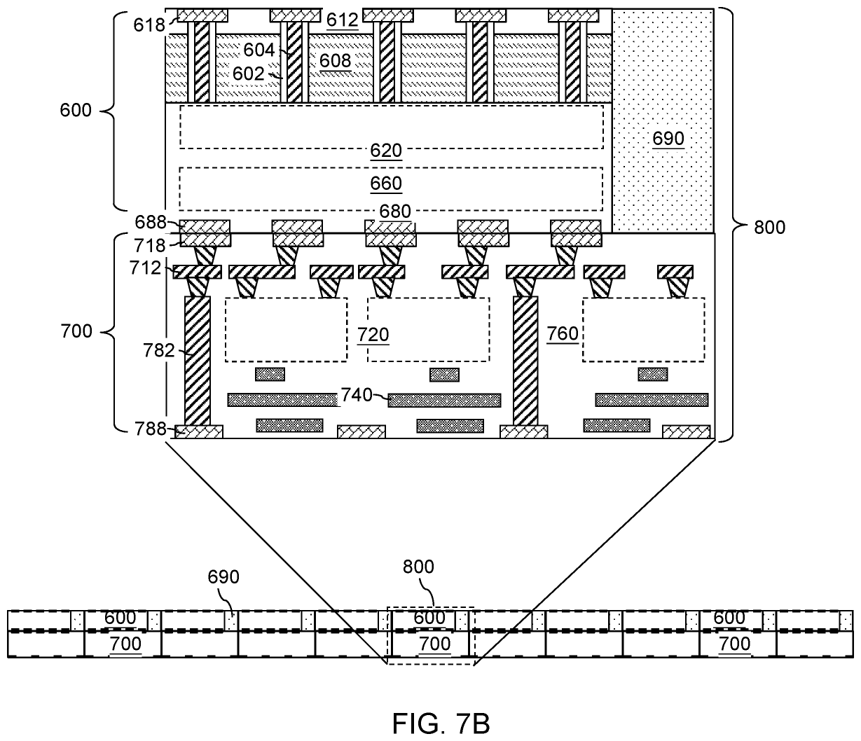

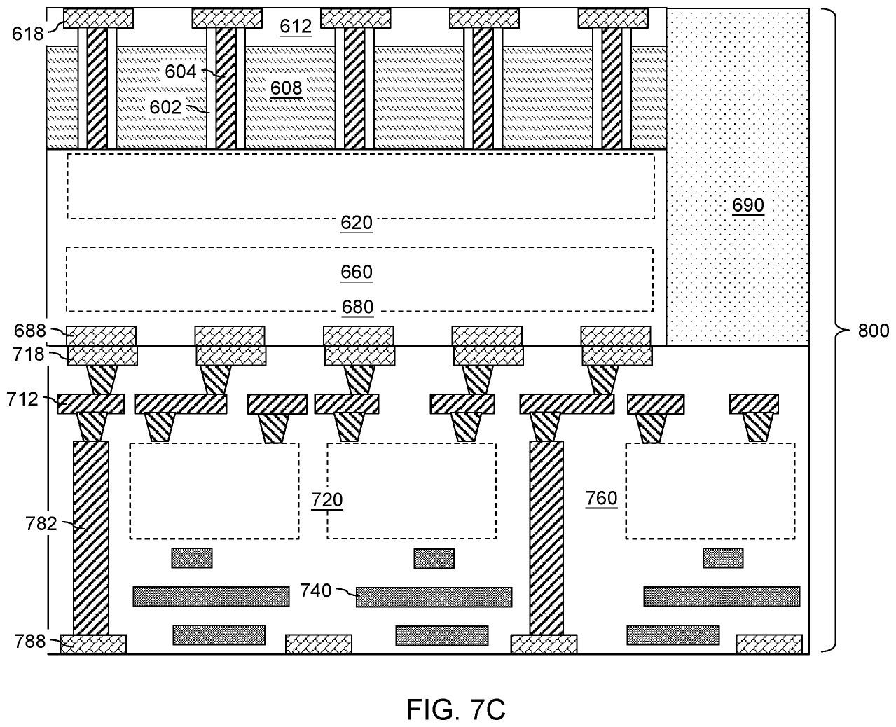

Referring to FIG. 7A, a bonded assembly including an array of photonic-electronic die assemblies is illustrated. The inset provides a magnified view of a photonic-electronic die assembly 800. The bonded assembly illustrated in FIG. 7A may be derived from the wafer illustrated in FIG. 1 by attaching an array of electronic dies 600 to the array of photonic dies 700 using metal-to-metal bonding such as copper-to-copper bonding.

Each electronic die 600 includes an electronic-die substrate 608, electronic-die through-substrate via structure 604 vertically extending through the electronic-die substrate 608 and laterally spaced from the electronic-die substrate 608 by tubular insulating spacers 602, electronic integrated circuits 620 configured to control operation of the photonic devices 720 based on instructions from an external semiconductor die such as a processor die 310 or a memory die 410, electronic-die metal interconnect structures 680 formed within electronic-die dielectric material layers 660, distal electronic-die bonding pads 688 that are configured for metal-to-metal bonding (such as copper-to-copper bonding) and electrically connected to the electronic-die metal interconnect structures 680, an electronic-die backside dielectric layer 612 which is located on a backside surface of the electronic-die substrate 608, and proximal electronic-die bonding pads 618 that are formed within the electronic-die backside dielectric layer 612 and configured for metal-to-metal bonding (such as copper-to-copper bonding).

The electronic integrated circuits 620 may comprise field effect transistors, diodes, resistors, capacitors, inductors, or various other types of semiconductor devices that may be manufactured on a semiconductor substrate. The distal electronic-die bonding pads 688 may be arranged in a mirror image pattern of the pattern of a subset of proximal photonic-die bonding pads 718 of a photonic die 700. According to an aspect of the present disclosure, the electronic die 600 may have a lesser area than a photonic die 700. Thus, each electronic die 600 may fit within the area of a respective underlying photonic die 700 in a plan view upon bonding the array of electronic dies 600 to the array of photonic dies 700. The proximal electronic-die bonding pads 618 may be arranged in a mirror image pattern of the pattern of a subset of bonding pads 388 of processor dies 310 to be subsequently used, or in a mirror image pattern of the pattern of a subset of bonding pads 488 of a memory die 410 to be subsequently used.

In one embodiment, each photonic die 700 comprises distal photonic-die bonding pads 788 and proximal photonic-die bonding pads 718, and each electronic die 600 comprises distal electronic-die bonding pads 688 and proximal electronic-die bonding pads 618. The proximal photonic-die bonding pads 718 of each photonic die may be bonded to the distal electronic-die bonding pads 688 of a respective one of the electronic dies 600 by metal-to-metal bonding (such as copper-to-copper bonding). In addition, a horizontal surface of the electronic-die dielectric material layers 660 of each electronic die 600 may be bonded to a horizontal surface of the photonic-die dielectric material layers 760 of a respective photonic die 700 via dielectric-to-dielectric bonding (such as silicon oxide-to-silicon oxide bonding).

Referring to FIG. 7B, a molding compound may be deposited into the gaps between neighboring pairs of electronic dies 600. The molding compound may comprise any material that may be used for formation of the molding compound matrices 390 described with reference to FIG. 4E. Excess portions of the molding compound may be removed from above the horizontal plane including the top surfaces of the electronic dies 600 by performing a planarization process, which may comprise a chemical mechanical polishing (CMP) process. The molding compound may be cured by performing an anneal process. A molding matrix 690 may be formed around the array of electronic dies 600.

Referring to FIG. 7C, the assembly of the wafer including the array of photonic dies 700, the array of electronic dies 600, and the molding matrix 690 may be diced along dicing channels. Each diced portion of the wafer comprises a bonded assembly including a photonic die 700 and an electronic die 600, which is herein referred to as a photonic-electronic die assembly 800.

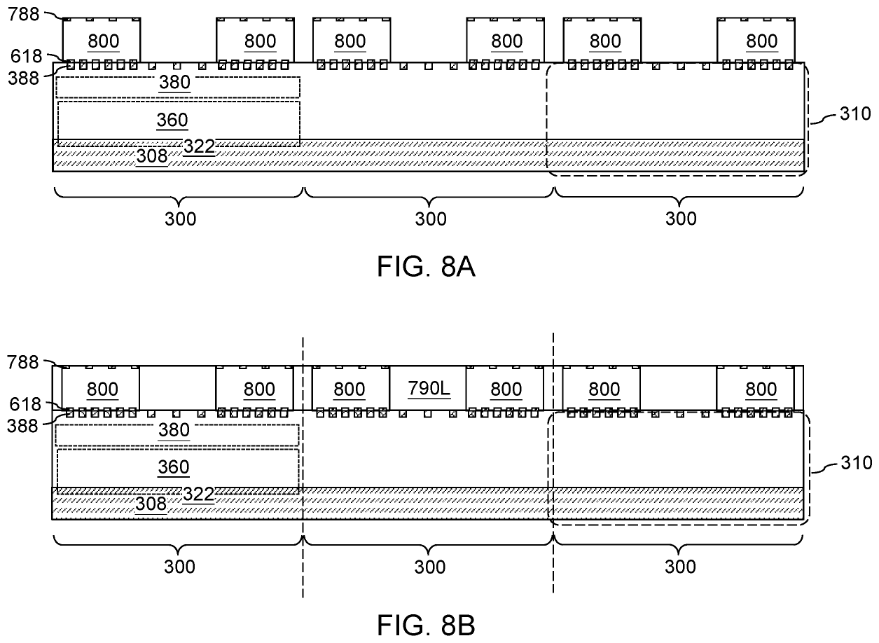

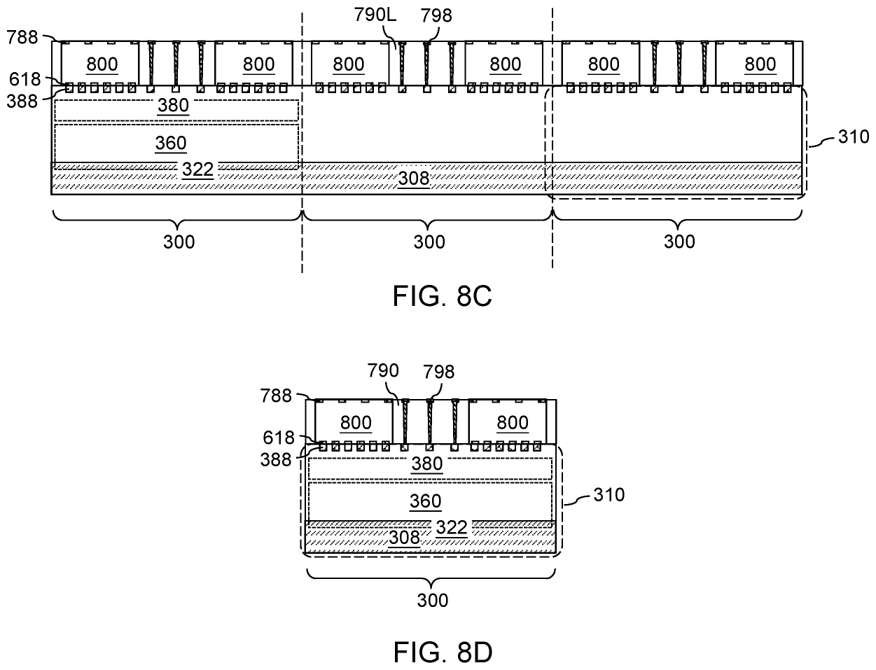

Referring to FIG. 8A, a semiconductor wafer including an array of semiconductor dies may be provided. The array of semiconductor dies may comprise a two-dimensional array of processor dies. Each processor die 310 includes at least one processing unit 322. Metal interconnect structures, which are herein referred to as processor-die metal interconnect structures 380, may be provided within each processor die 310. The processor-die metal interconnect structures 380 may be formed within dielectric material layers, which are herein referred to as processor-die dielectric material layers 360.

Bonding pads 388 may be provided within the topmost dielectric material layer selected from the processor-die dielectric material layers 360. The bonding pads 388 within the processor dies 310 are herein referred to as processor-die bonding pads or semiconductor-die bonding pads. The bonding pads 388 within each processor die 310 may comprise at least one set of first bonding pads 388 that are arranged in a mirror image pattern of the pattern of the proximal electronic-die bonding pads 618 of a photonic-electronic die assembly 800. In one embodiment, bonding pads 388 within a processor die 310 may comprise multiple sets of first bonding pads 388 that are arranged in mirror image patterns of the pattern of the proximal electronic-die bonding pads 618 of a photonic-electronic die assembly 800. The bonding pads 388 within each processor die 310 may comprise a set of second bonding pads 388 which does not belong to any set of first bonding pads 388. In embodiments in which multiple sets of first bonding pads 388 are provided within a processor die 310, a set of second bonding pads 388 may be provided between areas of sets of first bonding pads 388.

The photonic-electronic die assemblies 800 as provided after the processing steps described with reference to FIG. 7C may be bonded to the wafer including an array of semiconductor dies, which may be an array of processor dies 310. Each photonic-electronic die assembly 800 includes a bonded vertical stack of a photonic die 700 and an electronic die 600. In one embodiment, the proximal electronic-die bonding pads 618 of each photonic-electronic die assembly 800 may be bonded to a respective first subset of bonding pads 388 within the array of semiconductor dies (which may be an array of processor dies 310) by metal-to-metal bonding, such as copper-to-copper bonding. Each bonded assembly of a semiconductor die (such as a processor die 310) and at least one photonic-electronic die assembly 800 that is bonded to the semiconductor die constitutes a first assembly 300. A wafer including a two-dimensional array of first assemblies 300 may be provided. Each photonic-electronic die assembly 800 may comprise proximal electronic-die bonding pads 618 that are bonded to a respective subset of the bonding pads 388 in a respective underlying semiconductor die (such as a processor die 310), and distal photonic-die bonding pads 788 that are located at an opposite side of the proximal electronic-die bonding pads 618.

Referring to FIG. 8B, a planarizable dielectric material such as undoped silicate glass or a doped silicate glass may be deposited in the gaps between neighboring pairs of photonic-electronic die assemblies 800. The planarizable dielectric material may be deposited using a chemical vapor deposition process (such as a plasma-enhanced chemical vapor deposition process), or may be deposited by a spin-coating process. Excess portion s of the planarizable dielectric material may be removed from above the horizontal plane including the top surfaces of the photonic-electronic die assemblies 800 by performing a planarization process such as a chemical mechanical polishing (CMP) process. Remaining portions of the planarizable dielectric material constitutes a dielectric matrix layer 790L. The array of photonic-electronic die assemblies 800 may be laterally surrounded by the dielectric matrix layer 790L. In one embodiment, the dielectric matrix layer 790L may consist essentially of an inorganic dielectric material such as undoped silicate glass or a doped silicate glass.

Referring to FIG. 8C, a photoresist layer (not shown) may be applied over the top surfaces of the photonic-electronic die assemblies 800 and over the top surface of the dielectric matrix layer 790L, and may be lithographically patterned to form discrete openings over the areas of the second subset of the bonding pads 388 of the semiconductor dies (such as the processor dies 310) which are not bonded to the proximal electronic-die bonding pads 618. Discrete cylindrical openings may be formed in the photoresist layer.

A wet etch process may be optionally performed to isotropically etch portions of the dielectric matrix layer 790L that are proximal to bottom portions of the discrete cylindrical openings. An anisotropic etch process may be subsequently performed to transfer the pattern of the discrete cylindrical openings through the dielectric matrix layer 790L. Via cavities vertically extending through the dielectric matrix layer 790L to top surfaces of the second subset of the bonding pads 388 of the semiconductor dies (such as the processor dies 310) which are not bonded to the proximal photonic-die bonding pads 718. In one embodiment, the via cavities may have tapered sidewalls such that the lateral dimension of each via cavity decreases with a vertical distance downward from the photoresist layer. The photoresist layer may be subsequently removed, for example, by ashing.

At least one metallic material may be deposited in the via cavities and over the top surface of the dielectric matrix layer 790L. The at least one metallic material may comprise a combination of a metallic barrier liner material (such as TiN, TaN, WN, or MoN) and a metallic fill material comprising, and/or consisting essentially of, copper. The metallic barrier liner material may be deposited, for example, by chemical vapor deposition or physical vapor deposition. The metallic fill material may be deposited, for example, by electroplating. Excess portions of the at least one metallic material may be removed from above the horizontal plane including the top surfaces of the photonic-electronic die assemblies 800. Each remaining portion of the at least one metallic material that fill a respective via cavity constitutes a connection via structure 798. An array of connection via structures 798 may be formed through the dielectric matrix layer 790L on a second subset of the bonding pads 388 within each semiconductor dies (such as a processor die 310).

Referring to FIG. 8D, the wafer including the array of semiconductor dies (such as the processor dies 310), the photonic-electronic die assemblies 800, and the dielectric matrix layer 790L may be diced along dicing channels. Each diced portion of the wafer comprises a first assembly 300, which is a composite die including at least three dies. Specifically, each first assembly 300 comprises a semiconductor die (such as a processor die 310), at least one photonic-electronic die assembly 800 (each comprising a respective bonded pair of a photonic die 700 and an electronic die 600), and a dielectric matrix 790 which is a diced portion of the dielectric matrix layer 790L.

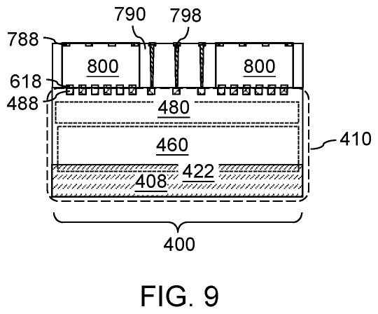

Referring to FIG. 9, a second assembly 400 of a semiconductor die, at least one photonic-electronic die assembly 800, and a dielectric matrix 790 is illustrated. The semiconductor die of the second assembly 400 may be a memory die 410, which may comprise a static random access memory (SRAM), a dynamic random access memory (DRAM), a magnetoresistive random access memory (RRAM), a high-bandwidth memory (HBM), or any other type of memory known in the art.

The memory die 410 may comprise a semiconductor substrate 408, and memory devices 422 formed in, on, or over, the semiconductor substrate 408. The memory devices 422 may comprise an SRAM, a DRAM, an RRAM, a HBM, or a combination thereof. Metal interconnect structures, which are herein referred to as memory-die metal interconnect structures 480, may be provided within each memory die 410. The memory-die metal interconnect structures 480 may be formed within dielectric material layers, which are herein referred to as memory-die dielectric material layers 460.

Bonding pads 488 may be provided within the topmost dielectric material layer selected from the processor-die dielectric material layers 360. The bonding pads 488 within the memory dies 410 are herein referred to as memory-die bonding pads or semiconductor-die bonding pads. The bonding pads 488 within each memory die 410 may comprise at least one set of first bonding pads 488 that are arranged in a mirror image pattern of the pattern of the proximal electronic-die bonding pads 618 of a photonic-electronic die assembly 800. In one embodiment, bonding pads 488 within a memory die 410 may comprise multiple sets of first bonding pads 488 that are arranged in mirror image patterns of the pattern of the proximal electronic-die bonding pads 618 of a photonic-electronic die assembly 800. The bonding pads 488 within each memory die 410 may comprise a set of second bonding pads 488 which does not belong to any set of first bonding pads 488. In embodiments in which multiple sets of first bonding pads 488 are provided within a memory die 410, a set of second bonding pads 488 may be provided between areas of sets of first bonding pads 488.

Generally, the processing steps described with reference to FIGS. 8A-8D may be performed with replacement of a wafer including a two-dimensional array of processor dies 310 with a wafer including a two-dimensional array of memory dies 410 to provide multiple instances of the second assembly 400 illustrated in FIG. 9, which is a composite die including a semiconductor die, at least one photonic-electronic die assembly 800, and a dielectric matrix 790.

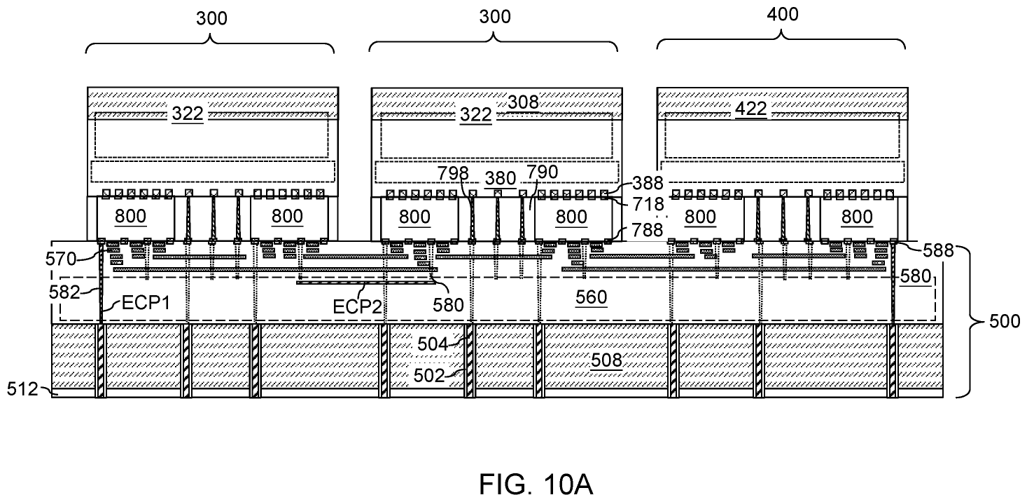

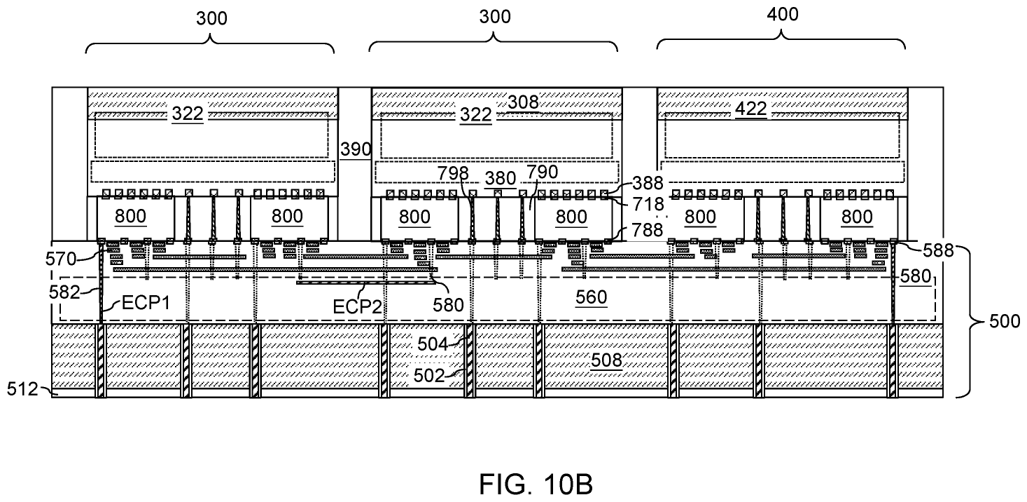

Referring to FIG. 10A, a passive optical interposer described with reference to FIG. 4C may be provided. A plurality of composite dies (300, 400) may be bonded to the passive optical interposer 500. The plurality of composite dies (300, 400) may comprise at least one first assembly 300 described with reference to FIG. 8D and at least one second assembly described with reference to FIG. 9. Generally, each first assembly 300, i.e., each first composite die, comprises a respective first semiconductor die (such as a processor die 310) and at least one respective first photonic-electronic die assembly 800. Each second assembly 400, i.e., each second composite die, comprises a second semiconductor die (such as a memory die 410) and at least one second photonic-electronic die assembly 800. The first assembly 300 may be attached to the passive optical interposer 500 such that a subset of the first waveguides 740 in each first photonic die 700 are optically coupled to a first subset of the interposer waveguides 570 in the passive optical interposer 500 through evanescent coupling. The second assembly 400 may be attached to the passive optical interposer 500 such that a subset of the second waveguides 740 in each second photonic die 700 are optically coupled to a second subset of the interposer waveguides 570 in the passive optical interposer 500 through evanescent coupling.

Each of the photonic-electronic die assemblies 800 comprises proximal electronic-die bonding pads 618 and distal photonic-die bonding pads 788. The distal photonic-die bonding pads 788 are located at an opposite side of the proximal electronic-die bonding pads 618. The distal photonic-die bonding pads 788 and the connection via structures 798 which are located within a first assembly 300 or within a second assembly 400 are bonded to interposer bonding pads 588 within the passive optical interposer 500 by metal-to-metal bonding, such as copper to copper bonding.

A semiconductor package is provided, which includes a passive optical interposer 500 comprising interposer dielectric material layers 560 embedding interposer waveguides 570 and interposer bonding pads 588. The semiconductor package includes at least one first composite die (which may be at least one first assembly 300) including a vertical stack of a respective first semiconductor die (such as a processor die 310) and at least one respective first photonic die 700. Each of the at least one first photonic die 700 comprises first photonic devices 720, first waveguides 740, first distal photonic-die bonding pads 788 that are bonded to a first subset of the interposer bonding pads 588, and first proximal photonic-die bonding pads 718 that are bonded to bonding pads 388 of the first semiconductor die (such as a processor die 310). The semiconductor package includes at least one second composite die (which may be at least one second assembly 400) including a vertical stack of a respective second semiconductor die (such as a memory die 410) and at least one respective second photonic die 700. Each of the at least one second photonic die 700 comprises second photonic devices 720, second waveguides 740, second distal photonic-die bonding pads 788 that are bonded to a second subset of the interposer bonding pads 588, and second proximal photonic-die bonding pads 718 that are bonded to bonding pads 488 of the second semiconductor die (such as a memory die 410).

The first distal photonic-die bonding pads 788 of each first photonic die 700 are bonded to the first subset of the interposer bonding pads 588 by metal-to-metal bonding. The second distal photonic-die bonding pads 788 of each second photonic die 700 are bonded to the second subset of the interposer bonding pads 588 by metal-to-metal bonding. First connection via structures 798 within each first assembly 300 may be bonded to a third subset of the interposer bonding pads 588 by metal-to-metal bonding. second connection via structures 798 within each second assembly 400 may be bonded to a fourth subset of the interposer bonding pads 588 by metal-to-metal bonding.

A subset of the interposer waveguides 570 laterally extends from a first region located underneath the at least one first photonic die 700 to a second region located underneath the at least one second photonic die 700. The subset of the interposer waveguides 570 may be optically coupled to waveguides 740 within the at least one first photonic die 700 via evanescent coupling, and may be optically coupled to waveguides 740 within the at least one second photonic die 700 via evanescent coupling.

The semiconductor package may comprise: a passive optical interposer 500 comprising interposer dielectric material layers 560 having formed therein interposer waveguides 570 and interposer bonding pads 588; a first composite die (which may be a composite processor-containing die 300) including a vertical stack of a first semiconductor die (such as a processor die 310), at least one first photonic die 700, and at least one first electronic die 600 interposed between the first semiconductor die (such as a processor die 310) and the at least one first photonic die 700 and configured to control operation of the at least one first photonic die 700, wherein each of the at least one first photonic die 700 comprises first photonic devices 720 and first waveguides 740; and a second composite die (which may be a composite memory-containing die 400) including a vertical stack of a second semiconductor die (such as a memory die 410), at least one second photonic die 700, and at least one second electronic die 600 interposed between the second semiconductor die (such as a memory die 410) and the at least one second photonic die 700 and configured to control operation of the at least one second photonic die 700, wherein each of the at least one second photonic die 700 comprises second photonic devices 720 and second waveguides 740.

In one embodiment, each of the at least one first electronic die 600 is bonded to a respective one of the at least one first photonic die 700 through first metal-to-metal bonding, and is bonded to the first semiconductor die (such as a processor die 310) through second metal-to-metal bonding. In one embodiment, each of the at least one first electronic die 600 is formed within a molding matrix 690 having sidewalls that are vertically coincident with sidewalls of a respective one of the first photonic dies 700.

In one embodiment, the first semiconductor die (such as a processor die 310) comprises at least one processing unit therein; and the second semiconductor die (such as a memory die 410) comprises a memory die. In one embodiment, the passive optical interposer 500 comprises: a semiconductor substrate 508; first electrically conductive paths ECP1 (which may comprise connection via structures 582 and may optionally comprise through-substrate via structures 504) vertically extending through the interposer dielectric material layers 560 and the semiconductor substrate 508; and second electrically conductive paths ECP2 (while may comprise a subset of the interposer metal interconnect structures 580) providing electrical connections between electrical nodes of the at least one first photonic die 700 and electrical nodes of the at least one second photonic die 700.

In one embodiment, dielectric-to-dielectric bonding may be used in addition to metal-to-metal bonding between the passive optical interposer 500 and each of the first assemblies 300 and the second assemblies 400. In one embodiment, each of the at least one first photonic die 700 comprises first photonic-die dielectric material layers 760 having formed therein the first distal photonic-die bonding pads 788 and first waveguides 740, and a surface of the first photonic-die dielectric material layers 760 is bonded to a surface segment of the interposer dielectric material layers 560 by dielectric-to-dielectric bonding (such as silicon oxide-to-silicon oxide bonding). In one embodiment, each of the at least one second photonic die 700 comprises second photonic-die dielectric material layers 760 having formed therein the second distal photonic-die bonding pads 788 and second waveguides 740, and a surface of the second photonic-die dielectric material layers 760 is bonded to a surface segment of the interposer dielectric material layers 560 by dielectric-to-dielectric bonding (such as silicon oxide-to-silicon oxide bonding).

In one embodiment, each first composite die (i.e., each first assembly 300) comprises a first dielectric matrix 790 laterally surrounding the at least one first photonic die 700 and contacting a planar surface of a first semiconductor die (such as a processor die 310), and first connection via structures 798 vertically extending through a first dielectric matrix 790, having first end surfaces that are bonded to a subset of bonding pads 388 within the first semiconductor die, and having second end surfaces that are bonded to a subset of the interposer bonding pads 588. In one embodiment, each second composite die (i.e., each second assembly 400) comprises a second dielectric matrix 790 laterally surrounding the at least one second photonic die 700 and contacting a planar surface of a second semiconductor die (such as a memory die 410), and second connection via structures 798 vertically extending through a second dielectric matrix 790, having second end surfaces that are bonded to a subset of bonding pads 488 within the second semiconductor die, and having second end surfaces that are bonded to a subset of the interposer bonding pads 588.

Referring to FIG. 10B, an encapsulant, such as a molding compound (MC) may be applied into the gaps between neighboring pairs of composite dies (300, 400). The molding compound may include any material that may be used as the molding compound used at the processing steps described with reference to FIG. 4E. Excess portions of the molding compound may be removed from above the horizontal plane including the top surfaces of the composite dies (300, 400).

The MC may be cured at a curing temperature to form a molding compound matrix layer. The molding compound matrix layer may be a continuous material layer that extends across the entirety of the area of the wafer including the two-dimensional array of passive optical interposers 500 and the composite dies (300, 400) that are bonded to the passive optical interposers 500. A reconstituted wafer is thus formed, which includes the two-dimensional array of passive optical interposers 500, the composite dies (300, 400) thereupon, and the molding compound matrix layer.

The reconstituted wafer may be subsequently diced along dicing channels, which correspond to the boundaries between neighboring pairs of passive optical interposers 500. Each singulated portion of the reconstituted wafer comprises a semiconductor structure including an assembly of a passive optical interposer 500, a plurality of composite dies (300, 400), and a molding compound matrix 390 which is portion of the molding compound matrix layer. Sidewalls of the molding compound matrix 390 may be vertically coincident with sidewalls of the passive optical interposer 500 within each assembly.

Generally, the processor dies 310 and the memory dies 410 located within each assembly of a passive optical interposer 500, a plurality of composite dies (300, 400), and a molding compound matrix 390 may be optically connected and/or may be electrically connected as described with reference to FIGS. 5A-5C.

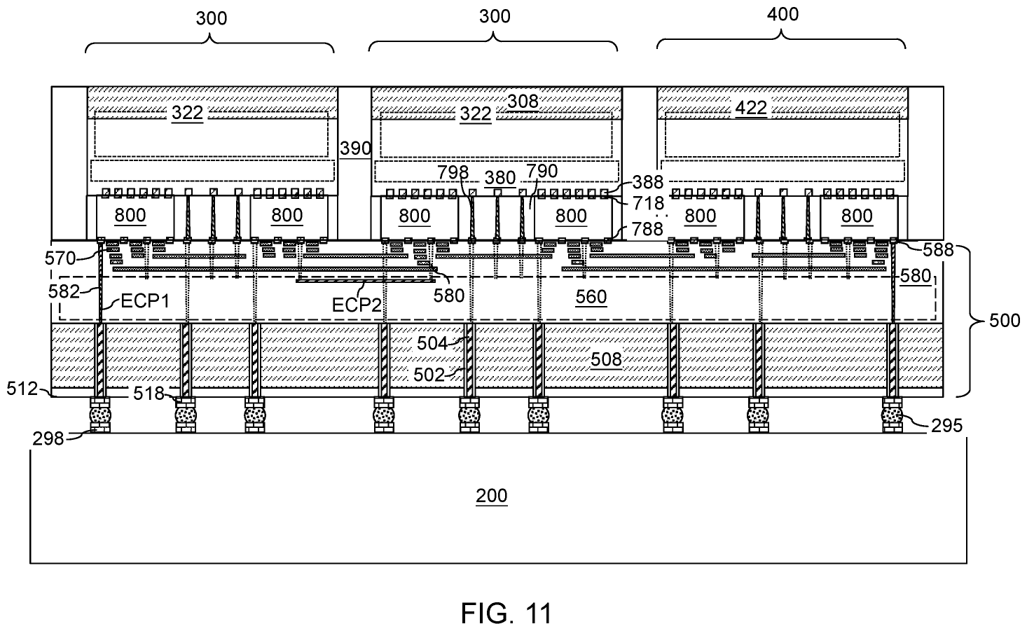

Referring to FIG. 11, the processing steps described with reference to FIG. 6 may be performed to attach the assembly of a passive optical interposer 500, a plurality of composite dies (300, 400), and a molding compound matrix 390 to a packaging substrate 200.

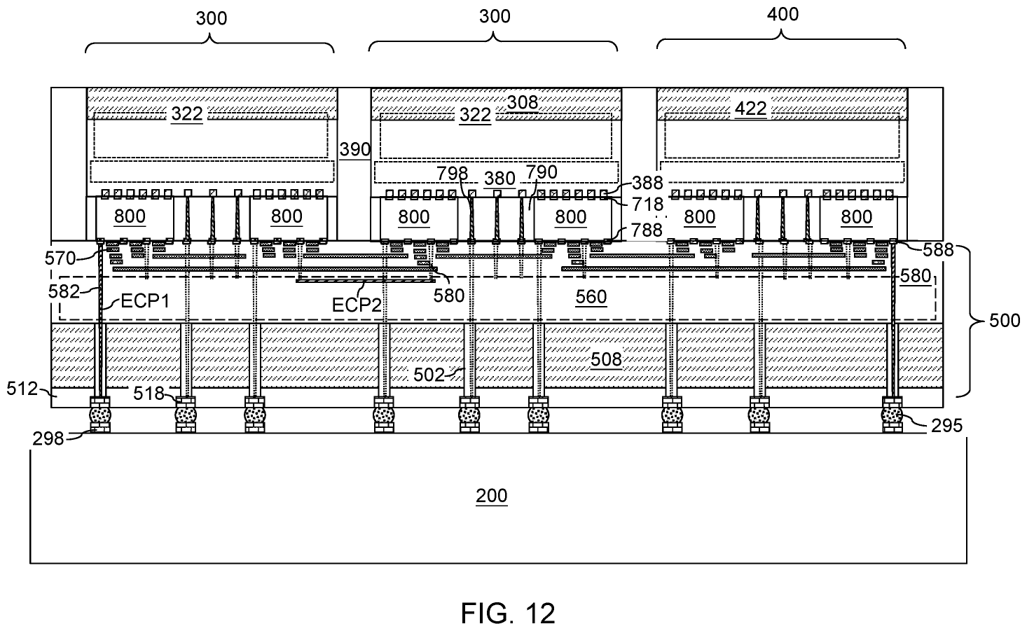

Referring to FIG. 12, an alternative configuration for the bonded assemblies illustrated in FIGS. 6 and 11 is illustrated. In this alternative configuration, the connection via structures 582 may vertically extend through the insulating spacers 502 within the semiconductor substrate 508. In this embodiment, a subset or all of the through-substrate via structures 504 within the passive optical interposer 500 may be omitted. In one embodiment, the connection via structures 582 may vertically extend between a respective pair of an interposer bonding pad 588 (which is also referred to as interposer front bonding pads) and a backside interposer bonding pad 518.

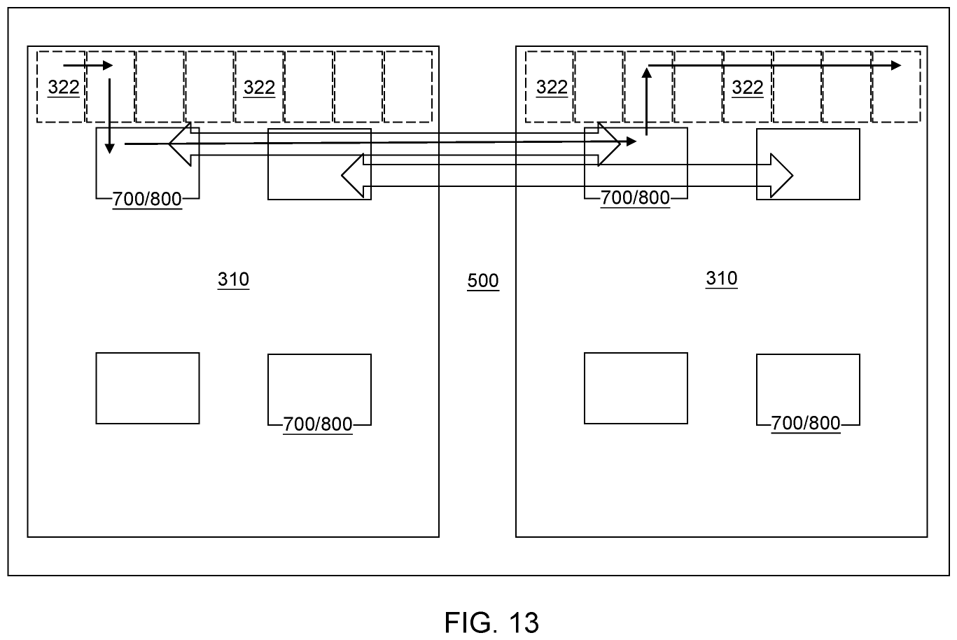

Referring to FIG. 13, a schematic for optical transmission of data between a pair of processing units 322 located in different processor dies 310 within a semiconductor package of the present disclosure is illustrated. The semiconductor package includes a bonded assembly of a passive optical interposer 500, at least two first assemblies 300 including a respective processor die 310 and a respective set of at least one photonic die 700 or a respective set of at least one photonic-electronic die assembly 800, and optionally at least one second assembly 400 (not shown) including a respective memory die 410 and a respective set of at least one photonic die 700 or a respective set of at least one photonic-electronic die assembly 800. In the illustrated example, each processor die 310 comprises a plurality of processing units 322. Eight processing units 322 are shown for each processor die 310.

In the illustrated data transmission operation, data from the leftmost processing unit 322 of the left-side processor die 310 in the left-side assembly 300 may be transferred to a processing unit 322 that is proximal to a photonic die 700 or a photonic-electronic die assembly 800. The data passes through an electronic integrated circuit 324 or an electronic die 600 within the photonic-electronic die assembly 800, then passes through the photonic die 700 and is converted into optical signals that pass through the waveguides 740 within the photonic die 700 and then through a set of interposer waveguides 570. The optical signal passes through the waveguides 740 within the photonic die 700 or the photonic-electronic die assembly 800 in the right-side assembly 300. The optical signal is converted into electrical signals by the photonic die 700 or the photonic-electronic die assembly 800, passes through the electronic integrated circuit 324 of the right-side processor die 310 or the electronic die 600 within the right-side assembly 300, is transferred to a processing unit 322 that is proximal to the electronic integrated circuit 324 or the electronic die 600, passes through a series of processing units 322 in the right-side processor die 310, and arrives at a destination processing unit 322, which is the rightmost processing unit 322 of the right-side processor die 310 in this illustrated example.

In this illustrated example, the data transfer path includes a total of 8 additional processing units 322 excluding the data origin processing unit 322, and the optical data paths provided by the passive optical interposer and a pair of optical communication dies which may be photonic dies 700 or photonic-electronic die assemblies 800. In this embodiment, the photonic dies 700 or photonic-electronic die assemblies 800 function as compact universal photonic engines (COUPEs). A COUPE includes a combination of photonic integrated circuits and electronic integrated circuits that provides optical-electrical transmission. A COUPE allows processing of optical signals using an electronic signal transmission system. A COUPE integrates various optical components, electro-optics transition devices, and optical fibers. In optical-electrical devices, laser light plays a pivotal role.

By providing optical signal communication paths within the passive optical interposer 500, a large number of semiconductor dies (310, 410) may be integrated on the passive optical interposer with wide communication bandwidths. Thus, the devices of the present disclosure provide an architecture in which a large number of processor dies 310 and memory dies 410 may be integrated without limitation on the communication bandwidths.

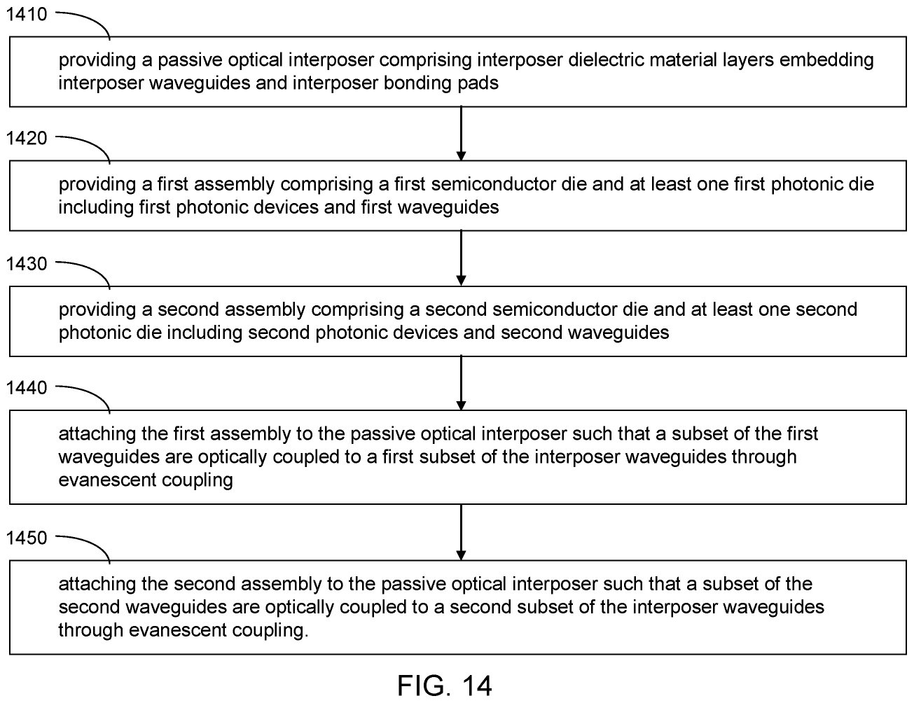

FIG. 14 is a flowchart illustrating general processing steps for forming a photonic semiconductor package of the present disclosure.

Referring to step 1410 and FIGS. 4A-4C, a passive optical interposer 500 comprising interposer dielectric material layers 560 having formed therein interposer waveguides 570 and interposer bonding pads 588 may be provided.

Referring to step 1420 and FIGS. 1, 2A-2D, and 7A-8D, a first assembly 300 comprising a first semiconductor die (such as a processor die 310) and at least one first photonic die 700 including first photonic devices 720 and first waveguides 740 may be provided.

Referring to step 1430 and FIGS. 1, 2A-2D, 3, 7A-8D, and 9, a second assembly 400 comprising a second semiconductor die (such as a memory die 410) and at least one second photonic die 700 including second photonic devices 720 and second waveguides 740 may be provided.

Referring to step 1440 and FIGS. 4D and 10A, the first assembly 300 is attached to the passive optical interposer 500 such that a subset of the first waveguides 740 are optically coupled to a first subset of the interposer waveguides 570 through evanescent coupling.

Referring to step 1450 and FIGS. 4D and 10A, the second assembly 400 may be attached to the passive optical interposer 500 such that a subset of the second waveguides 740 are optically coupled to a second subset of the interposer waveguides 570 through evanescent coupling.

Embodiments of the present disclosure may be used to enhance performance of a computing system by solving the memory wall problem, and thus, provides the computing system to achieve a higher performance level for high-end computing systems such as those for high performance computing (HPC) and artificial intelligence (AI) applications. The optical connections through the passive optical interposer 500 of the disclosure provide a cache linkage system, which is a scalable solution to memory bandwidth and latency issues, allowing for future advancements in computing system design and application requirements. Thermal issues in the computing system may be avoided by the placement of semiconductor dies that generate excessive heat in peripheral regions of the computing system, or by providing sufficient spacing around such semiconductor dies. For example, semiconductor dies including a respective vertically stack of DRAMs may be positioned farther away from other semiconductor dies to reduce the adverse thermal effect on adjacent semiconductor dies, mitigating one of the major challenges in modern computing system design. Embodiments of the present disclosure offer a robust solution to some of the most pressing challenges in system performance and design. The optical links in the passive optical interposer provide scalable data connection paths for enhancing for efficiency, performance, and reliability in high-performance computing systems.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor package comprising:
providing a passive optical interposer comprising interposer dielectric material layers having formed therein interposer waveguides and interposer bonding pads;
providing a first assembly comprising a first semiconductor die and at least one first photonic die including first photonic devices and first waveguides;
providing a second assembly comprising a second semiconductor die and at least one second photonic die including second photonic devices and second waveguides;
attaching the first assembly to the passive optical interposer such that a subset of the first waveguides are optically coupled to a first subset of the interposer waveguides through evanescent coupling; and
attaching the second assembly to the passive optical interposer such that a subset of the second waveguides are optically coupled to a second subset of the interposer waveguides through evanescent coupling.

2. The method of claim 1, wherein:
each of the at least one first photonic die comprises first proximal bonding pads and first distal bonding pads; and
the method comprises bonding the first proximal bonding pads of each of the at least one first photonic die to bonding pads within the first semiconductor die through metal-to-metal bonding during formation of the first assembly.

3. The method of claim 2, wherein the first semiconductor die embeds at least one electronic integrated circuit that is electrically connected to a respective one of the at least one first photonic die.

4. The method of claim 1, further comprising:
bonding at least one first electronic die to a respective one of the at least one first photonic die; and
bonding each assembly of a respective first electronic die and a respective first photonic die to the first semiconductor die.

5. The method of claim 4, wherein:
each of the at least one first photonic die comprises first distal photonic-die bonding pads and first proximal photonic-die bonding pads;
each of the at least one first electronic die comprises first distal electronic-die bonding pads and first proximal electronic-die bonding pads;
the method comprises bonding the first proximal photonic-die bonding pads to the first distal electronic-die bonding pads of a respective one of the at least one first electronic die by metal-to-metal bonding; and
the method comprises bonding the first proximal electronic-die bonding pads to bonding pads of the first semiconductor die.

6. The method of claim 4, further comprising:
providing a wafer including an array of photonic dies;
attaching an array of electronic dies to the array of photonic dies using metal-to-metal bonding;
forming a molding matrix around the array of electronic dies; and
dicing an assembly of the wafer, the array of electronic dies, and the molding matrix, wherein a subset of diced portions of the assembly comprises at least one bonded assembly including the at least one first electronic die and the at least one first photonic die.

7. The method of claim 1, wherein the first assembly is provided by:
providing a wafer including an array of semiconductor dies;
attaching an array of photonic dies to the array of semiconductor dies;
forming a dielectric matrix layer around the array of photonic dies; and
dicing a bonded assembly of the wafer, the array of photonic dies, and the dielectric matrix layer, wherein a diced portion of the bonded assembly comprises the first assembly.

8. The method of claim 7, wherein:
each of the array of photonic dies comprise proximal photonic-die bonding pads that are bonded to a first subset of bonding pads within the array of semiconductor dies; and
the method comprises forming connection via structures through the dielectric matrix layer on a second subset of the bonding pads within the array of semiconductor dies.

9. The method of claim 8, wherein:
each of the array of photonic dies comprise distal photonic-die bonding pads that are located at an opposite side of the proximal photonic-die bonding pads; and
the distal photonic-die bonding pads and the connection via structures which are located within the first assembly are bonded to interposer bonding pads within the passive optical interposer by metal-to-metal bonding.

10. The method of claim 1, wherein the first assembly is provided by:
providing a wafer including an array of semiconductor dies;
providing vertical stack s of a respective photonic die and a respective electronic die;
attaching the vertical stack s to the array of semiconductor dies;
forming a dielectric matrix layer around an array of the vertical stacks; and
dicing a bonded assembly of the wafer, the array of the vertical stacks, and the dielectric matrix layer, wherein a diced portion of the bonded assembly comprises the first assembly.

11. A semiconductor package comprising:
a passive optical interposer comprising interposer dielectric material layers having formed therein interposer waveguides and interposer bonding pads;
a first composite die including a vertical stack of a first semiconductor die and at least one first photonic die, wherein each of the at least one first photonic die comprises first photonic devices, first waveguides, first distal bonding pads that are bonded to a first subset of the interposer bonding pads, and first proximal bonding pads that are bonded to bonding pads of the first semiconductor die; and
a second composite die including a vertical stack of a second semiconductor die and at least one second photonic die, wherein each of the at least one second photonic die comprises second photonic devices, second waveguides, second distal bonding pads that are bonded to a second subset of the interposer bonding pads, and second proximal bonding pads that are bonded to bonding pads of the second semiconductor die.

12. The semiconductor package of claim 11, wherein a subset of the interposer waveguides laterally extends from a first region located underneath the at least one first photonic die to a second region located underneath the at least one second photonic die.

13. The semiconductor package of claim 11, wherein the first distal bonding pads are bonded to the first subset of the interposer bonding pads by metal-to-metal bonding.

14. The semiconductor package of claim 13, wherein:
each of the at least one first photonic die comprises first photonic-die dielectric material layers having formed therein the first distal bonding pads and first waveguides; and
a surface of the first photonic-die dielectric material layers is bonded to a surface segment of the interposer dielectric material layers by dielectric-to-dielectric bonding.

15. The semiconductor package of claim 11, wherein the first composite die comprises:
a first dielectric matrix laterally surrounding the at least one first photonic die and contacting a planar surface of the first semiconductor die; and
first connection via structures vertically extending through the first dielectric matrix, having first end surfaces that are bonded to a subset of bonding pads within the first semiconductor die, and having second end surfaces that are bonded to a subset of the interposer bonding pads.

16. A semiconductor package comprising:
a passive optical interposer comprising interposer dielectric material layers having formed therein interposer waveguides and interposer bonding pads;
a first composite die including a vertical stack of a first semiconductor die, at least one first photonic die, and at least one first electronic die interposed between the first semiconductor die and the at least one first photonic die and configured to control operation of the at least one first photonic die, wherein each of the at least one first photonic die comprises first photonic devices and first waveguides; and
a second composite die including a vertical stack of a second semiconductor die, at least one second photonic die, and at least one second electronic die interposed between the second semiconductor die and the at least one second photonic die and configured to control operation of the at least one second photonic die, wherein each of the at least one second photonic die comprises second photonic devices and second waveguides.

17. The semiconductor package of claim 16, wherein each of the at least one first electronic die is bonded to a respective one of the at least one first photonic die through first metal-to-metal bonding, and is bonded to the first semiconductor die through second metal-to-metal bonding.

18. The semiconductor package of claim 16, wherein each of the at least one first electronic die is formed within a molding matrix having sidewalls that are vertically coincident with sidewalls of a respective one of the first photonic dies.

19. The semiconductor package of claim 16, wherein:
the first semiconductor die comprises at least one processing unit therein; and
the second semiconductor die comprises a memory die.

20. The semiconductor package of claim 16, wherein the passive optical interposer comprises:
a semiconductor substrate;
first electrically conductive paths vertically extending through the interposer dielectric material layers and the semiconductor substrate; and
second electrically conductive paths providing electrical connections between electrical nodes of the at least one first photonic die and electrical nodes of the at least one second photonic die.
